(19) United States
(12) Patent Application Publication
(10) Pub. No.: US 2006/0068104 A1
(43) Pub. Date: Mar. 30, 2006

(54) Thin-film formation in semiconductor device fabrication process and film deposition apparatus

(75) Inventors: Tadahiro Ishizaka, Nirasaki-Shi (JP); Yasuhiro Oshima, Nirasaki-Shi (JP); Naoki Yoshii, Nirasaki-Shi (JP); Takashi Shigeoka, Yokohama-Shi (JP); Kohei Kawamura, Nirasaki-Shi (JP); Yukio Fukuda, Nakakoma-Gun (JP); Yasuhiko Kojima, Nirasaki-Shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/231,962

(22) Filed: Sep. 22, 2005

Related U.S. Application Data
(63) Continuation of application No. PCT/JP04/06060, filed on Apr. 27, 2004.

(30) Foreign Application Priority Data
Jun. 16, 2003 (JP) 2003-170950
Mar. 12, 2004 (JP) 2004-070144

(51) Int. Cl. C23C 16/00

(52) U.S. Cl. 427/248.1; 118/715; 118/723 R

(57) ABSTRACT

A film fabrication method for forming a film over a substrate in a processing chamber includes a first film formation process and a second film formation process. In the first film formation process, (a) a first step of supplying a first source gas containing a metal-organic compound and without containing a halogen element into the chamber and then removing the first source gas from the chamber, and (b) a second step of supplying a second source gas containing hydrogen or a hydrogen compound into the chamber and then removing the second source gas from the chamber, are repeated a predetermined number of times. In the second film formation process, (c) a third step of supplying a third source gas containing a metal halide compound into the chamber and then removing the third gas from the chamber, and (d) a fourth step of supplying a plasma-activated fourth source gas containing hydrogen or a hydrogen compound into the chamber and then removing the fourth source gas from the chamber, are repeated a predetermined number of times.

### CROSS REFERENCE

This application is a continuation application filed under 35 USC 111(a) claiming benefit under 35 USC 120 and 365(c) of PCT application JP04/006060, filed Apr. 27, 2004, the entire contents of which are incorporated herein by reference.

### FIELD OF THE INVENTION

The present invention relates to thin-film formation on a semiconductor substrate, and more particularly, to a technique for fabricating a barrier film for preventing diffusion of metal species, without damaging underlying layers.

### BACKGROUND OF THE INVENTION

Along with recent and continuing demand for high-performance semiconductor devices, highly integrated semiconductor devices are being developed with further miniaturization scales. The design rule of metal processes is shifting from 0.13 μm to 0.10 μm or even smaller. Concerning the material of interconnects, conventionally used aluminum (Al) is being replaced with copper (Cu), which material has a lower electric resistance and less influence of wiring delay.

For this reason, the combination of copper (Cu) film formation and fine-pitch wiring technology becomes more important in the recent technology for fabricating high-performance semiconductor devices.

When employing copper (Cu) interconnects, it is necessary to form a Cu-diffusion barrier film to prevent copper species from diffusing into the surrounding dielectric (or insulating) film. Such a diffusion barrier film requires high film quality with less impurity content and satisfactory crystal orientation. It is also required for the diffusion barrier film to achieve high coverage on the minute patterns.

Atomic layer deposition (ALD) is one of film formation techniques satisfying the above-described requirements. With atomic layer deposition, one of multiple types of source gases is supplied alternately onto the substrate to form an atom layer or a molecular layer one by one through adsorption of the source gas onto the substrate surface. By repeating the layer-by-layer film formation (atomic layers or molecular layers), a thin film with a predetermined thickness can be fabricated.

To be more precise, the first source gas is supplied onto the substrate to form the adsorbed layer of the first material. Then the second source gas is supplied onto the substrate to cause the second gas to react with the first material. Since the second source gas reacts with the first source gas after adsorption onto the substrate, the temperature in film formation can be lowered. The amount of impurities in the film is smaller, and a high-quality thin film can be obtained. In addition, high coverage can be achieved over minute patterns, while preventing undesirable voids from being generated. Such voids are generated in the conventional CVD method when the source gas is reactively consumed over the holes.

High refractory metals or nitrides thereof are typically used as the copper (Cu) diffusion barrier film. It is currently known that titanium nitride (TiN) film, tantalum (Ta) film. tantalum nitride (TaN) film, Ta/TaN layered film, tungsten (W) film, tungsten nitride (WN) film, and W/WN layered film can be employed as the copper diffusion barrier film.

For example, when forming a titanium nitride (TiN) film, the first source gas is a chemical compound containing titanium (Ti), such as TiCl₄, and the second source gas is a reducing gas containing nitrogen, such as plasma-activated NH₃. The reason why plasma-activated NH₃ is used is to reduce the impurity density in the TiN film.

With the layer-by-layer deposition, by supplying the first source gas to form the adsorbed layer on the substrate and then supplying the second source gas, a high-quality TiN film with less impurities and lower resistance can be formed.

The above-described background technologies are disclosed in, for example, patent laid-open publications JP 6-89873A and JP 7-252660A. They are also disclosed in non-patent publications, such as
1) K-K. Elers, V. Saanila, P.S. Soininen & S. Haukka, “The Atomic Layer CVD growth of titanium nitride from in-situ reduced titanium chloride” in Proceedings of Advanced Metallization Conference 2000, 2000, at 35-36;
2) S. B. Kang, Y. S. Chae, M. Y. Yoon, H. S. Leen, C. S. Park, S. I. Lee & M. Y. Lee, “Low temperature processing of conformal TiN by ACVD (Advanced Chemical Vapor Deposition) for multilevel metallization in high density ULSI devices” in Proceedings of International Interconnects Technology Conference 1998, 1998, at 102-104;
3) W. M. Li, K. Elers, J. Kostamo, S. Kaipio, H. Huotari, M. Soinien, M. Tuominen, S. Smith & W. Besling, “Deposition of WNxCy thin film by ALCVDTM method for diffusion barriers in metallization” in Proceedings of International Interconnects Technology Conference 2002, 2002; and
4) J. S. Park, M. J. Lee, C. S. Lee & S. W. Kang, “Plasma-enhanced atomic layer deposition of tantalum nitrides using hydrogen radicals as a reducing agent”, Electrochemical & Solid-State Lett., 2001, 4, at 17-19.

However, a problem arises when employing atom-layer level or molecular-layer level film deposition to form a copper (Cu) diffusion barrier film. That is, the underlayers existing beneath the Cu diffusion barrier layer are damaged.

For example, when forming copper (Cu) interconnects by dual damascene, lower-level copper (Cu) interconnects or tungsten (W) interconnects exist under the copper (Cu) diffusion barrier film. There is also interlayer dielectric film existing around the upper-level Cu interconnects.

If a TiN film is formed as the Cu diffusion barrier film, the interlayer dielectric film is damaged by the plasma process. Since the second source gas NH₃ is plasma-activated, the ions and radicals dissociated from NH₃ damage the dielectric film. In particular, low dielectric constant films are often used as the dielectric film in these years. If such low dielectric constant films are damaged by ions and/or radicals, permittivity of the dielectric film becomes high.

The lower-level Cu interconnects are also damaged by the fabrication process of the Cu diffusion barrier film. Again, if a TiN film is formed as the Cu diffusion barrier film, the lower-level Cu interconnects are corroded by halogen and the copper surface is roughened because metal halide TiCl₄ gas is used as the first source gas.

### SUMMARY OF THE INVENTION

Therefore, it is an object of the present invention to solve the above-described problems in the prior art, and to provide a novel and useful film formation technique that does not damage underlayers when forming a Cu-diffusion barrier film, while achieving high film quality.

In particular, it is an object of the invention to provide a film fabrication method for fabricating a high-quality Cu-diffusion barrier film with less impurities contained therein, without damaging the underlying dielectric film.

It is also an object of the invention to provide a film fabrication method for fabricating a high-quality Cu-diffusion barrier film with less impurities contained therein, without damaging the underlying copper film.

To achieve the objects, in the first aspect of the invention, a film fabrication method for forming a film over a substrate in a processing chamber is provided. The film fabrication method includes a first film formation process and a second film formation process. In the first film formation process, (a) a first step of supplying a first source gas containing a metal into a chamber and then removing the first source gas from the chamber, and (b) a second step of supplying a second source gas containing hydrogen or a hydrogen compound into the chamber and then removing the second source gas from the chamber, are repeated a predetermined number of times. In the second film formation process,

(c) a third step of supplying the first source gas into the chamber and removing the first gas from the chamber, and (d) a fourth step of supplying a plasma-activated third source gas containing hydrogen or a hydrogen compound into the chamber and removing the third source gas from the chamber, are repeated a predetermined number of times.

In the second aspect of the invention, a film fabrication method for forming a film over a substrate in a processing chamber includes a first film formation process and a second film formation process. In the first film formation process, (a) a first step of supplying a first source gas containing an organic-metal compound and without containing a halogen element into the chamber and then removing the first source gas from the chamber, and (b) a second step of supplying a second source gas containing hydrogen or a hydrogen compound into the chamber and then removing the second source gas from the chamber, are repeated a predetermined number of times. In the second film formation process, (c) a third step of supplying a third source gas containing a metal halide compound into the chamber and then removing the third gas from the chamber, and (d) a fourth step of supplying a plasma-activated fourth source gas containing hydrogen or a hydrogen compound into the chamber and then removing the fourth source gas from the chamber, are repeated a predetermined number of times.

In the third aspect of the invention, a film fabrication method for forming a film over a substrate in a processing chamber includes a first film formation process and a second film formation process. In the first film formation process, (a) a first step of supplying a first source gas containing an organic-metal compound and without containing a halogen element into the chamber and then removing the first source gas from the chamber, and (b) a second step of supplying a second source gas containing hydrogen or a hydrogen compound into the chamber and then removing the second source gas from the chamber, are repeated a predetermined number of times. In the second film formation process, (c) a third step of supplying a third source gas containing a metal halide compound into the chamber and then removing the third gas from the chamber, and (d) a fourth step of supplying a plasma-activated fourth source gas containing hydrogen or a hydrogen compound into the chamber and then removing the fourth source gas from the chamber, are repeated a predetermined number of times.

In these methods, the first film formation process is performed to form a first copper-diffusion barrier film, and the second film formation process is performed to form a second copper-diffusion barrier film. Thus, a layered barrier film for preventing copper diffusion is obtained.

With the above-described methods, the Cu-diffusion barrier film can be formed without damaging underlying layers.

The resultant Cu-diffusion barrier film has a satisfactory film quality with less impurity content and good crystal orientation. In addition, high coverage over a minute pattern can be achieved.

In the fourth aspect of the invention, a film deposition apparatus is provided. The apparatus 42 includes:

(a) a processing chamber;

(b) a stage configured to hold a substrate to be processed in the processing chamber;

(c) a first gas supply system configured to supply a first source gas or a third source gas into the processing chamber;

(d) a second gas supply system configured to supply a second source gas or a fourth source gas into the processing chamber, independently from the first gas supply system; and

(e) plasma excitation means configured to excite the second source gas or the fourth source gas into plasma.

With this apparatus, a layered film, such as a layered copper-diffusion barrier film, can be formed without damaging underlying layers.

### BRIEF DESCRIPTION OF THE DRAWINGS

Other objects, features, and advantages of the invention will become more apparent from the following detailed description when read in conjunction with the accompanying drawings, in which

FIG. 1A through FIG. 1C illustrate a film fabrication process according to Example 1 of the preferred embodiment of the invention;

FIG. 2A through FIG. 2C illustrate a film fabrication process according to Example 2 of the preferred embodiment of the invention;

FIG. 3A through FIG. 3C illustrate a film fabrication process according to Example 3 of the preferred embodiment of the invention;

FIG. 4 is a schematic diagram illustrating a film fabrication apparatus used to implement a film fabrication method of the invention;

FIG. 5 is a flowchart of a film fabrication method according to Example 5 of the preferred embodiment of the invention;

FIG. 6 is a flowchart of a film fabrication method according to Example 6 of the preferred embodiment of the invention;

FIG. 7 is a flowchart of a film fabrication method according to Example 7 of the preferred embodiment of the invention;

FIG. 8A through FIG. 8F show a fabrication process of a semiconductor device to which the film fabrication method of the present invention is applied;

FIG. 9 is a schematic cross-sectional view of a semiconductor device fabricated using the film fabrication method of the present invention;

FIG. 10 is a schematic diagram illustrating another example of a film fabrication apparatus used to implement a film fabrication method of the invention;

FIG. 11 is a flowchart of a film fabrication method according to Example 12 of the preferred embodiment of the invention;

FIG. 12 is a table illustrating a set of conditions of the film fabrication method of Example 12;

FIG. 13 is a table illustrating another set of conditions of the film fabrication method of Example 12;

FIG. 14 illustrates the layered structure of a Cu-diffusion barrier film formed by the film fabrication method of Example 12;

FIG. 15A and FIG. 15B are charts showing the X-ray photoelectron spectroscopy (XPS) analysis results of a Ta(C)N film formed by the film fabrication method of Example 12;

FIG. 16 is a chart showing the X-ray diffraction (XRD) analysis result of a Ta(C)N film formed by the film fabrication method of Example 12;

FIG. 17 is a cross-sectional SEM (scanning electron microscope) photograph of a Ta(C)N film formed by the film fabrication method of Example 12;

FIG. 18 is a chart showing the XPS analysis result of a Ta film formed by the film fabrication method of Example 12;

FIG. 19 is a chart showing the XRD analysis result of a Ta film formed by the film fabrication method of Example 12;

FIG. 20 is a cross-sectional TEM (transmission electron microscope) photograph of a Ta film formed by the film fabrication method of Example 12; and

FIG. 21 a schematic diagram illustrating a film fabrication apparatus according to Example 13 of the preferred embodiment of the invention.

### DETAILED DESCRIPTION OF THE PREFERRED EMBODIMENT

With the present invention, a high-quality Cu-diffusion barrier film can be formed on a semiconductor substrate layer by layer (on the atomic layer basis or the molecular layer basic) the following steps. The first source gas is supplied onto the substrate held in a chamber to form a adsorbed layer on the substrate, and unreacted first source gas is removed from the chamber. Then, the second source gas is supplied onto the substrate in the chamber to cause reaction, and unreacted second source gas is removed from the chamber.

In this manner, film formation is carried out layer by layer (on the atomic or molecular layer basis), and a high-quality film with less impurities and low electric resistance can be obtained. When forming a Cu-diffusion barrier film over minute patterns, good coverage can be achieved with few voids generated due to reactive consumption of the source gas over the holes. In addition, the film fabrication method of the invention is superior in film quality and uniformity of film thickness on the processed substrate. In addition, the film fabrication method of the invention is advantageous because of the lowered process temperature, especially when a film likely to deteriorate at a high temperature (at or above 400° C.), such as a low dielectric constant film, is used in underlayers. The film fabrication method of the invention may be referred to as atomic layer deposition (ALD).

Actual examples of fabrication of a Cu-diffusion barrier film according to the preferred embodiment are now described below in conjunction with the attached drawings.

### Example 1

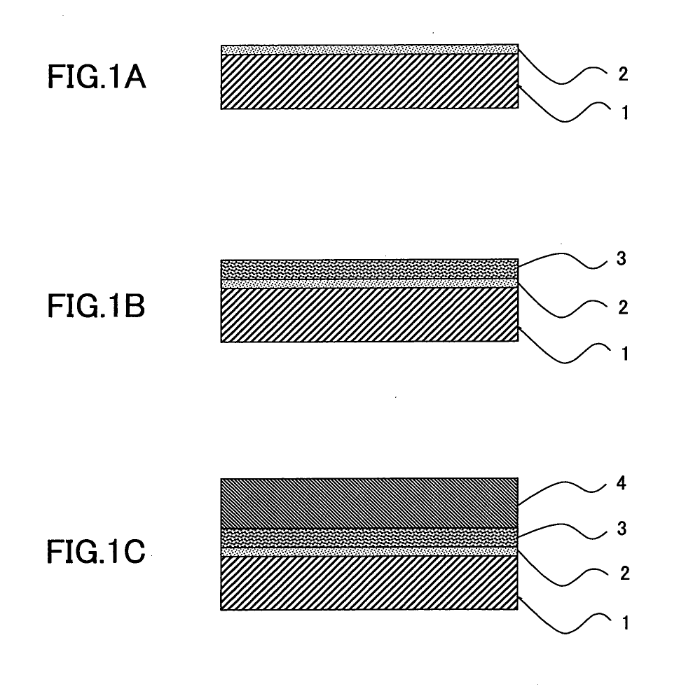

FIG. 1A through FIG. 1C illustrate a film fabrication method of Example 1. In Example 1, titanium nitride (TiN) film is formed as the Cu-diffusion barrier film over a dielectric (or insulating) film, without damaging the dielectric film.

In FIG. 1A, a first diffusion barrier film 2 is formed on the underlayer film 1 over a substrate (not shown). The first diffusion barrier metal 2 is formed by alternately supplying a first source gas and a second source gas onto the substrate. The first source gas is TiCl₄, and the second source gas is NH₃.

Then, as shown in FIG. 1B, a second Cu-diffusion barrier film 3 is formed over the first diffusion barrier film 2 by alternately supplying the first source gas and plasma-activated second source gas on to the substrate. Accordingly, TiCl₄ gas and plasma-activated NH₃ gas are supplied alternately.

Then, as shown in FIG. 1C, a copper (Cu) layer 4 is formed over the second Cu-diffusion barrier film 3 by PVD, CVD, or plating.

Because in the step shown in FIG. 1A unexcited NH₃ gas, which gas consists of electrically neutral species without containing damaging species, such as ions and radicals, is used as the second source gas, the fabrication of the first diffusion barrier film 2 does not damage the dielectric film 1.

In contrast, plasma-activated NH₃ gas contains radicals, such as N*, H*, or NH*, which radicals are likely to etch the dielectric film 1. In addition, ions existing in the plasma-activated NH₃ gas give physical sputtering damage to the dielectric film. The first step shown in FIG. 1A of Example 1 does not cause these problems.

Silicon dioxide film is conventionally used as the dielectric film 1; however, using low dielectric constant films with permittivity at or below 4 (which permittivity is lower as compared with ordinary silicon dioxide) has become more popular in the semiconductor industry in these years. Such low dielectric constant films are easy to be etched chemically or physically. The film quality is also likely to change, causing the permittivity to increase. When a porous film with a number of pores formed in the film to lower the permittivity is used as the dielectric film, the film is more likely to be damaged because of insufficient strength.

For the above-described reason, the film fabrication method of the present invention is more advantageous when forming a Cu-diffusion barrier film over a low dielectric constant film more likely to be damaged as compared with silicon dioxide film. Low dielectric constant film is roughly grouped into inorganic film and organic film. Examples of inorganic film include alkyl siloxane polymer and HSQ (hydrogenated silsesquioxane polymer), which are known as inorganic spin-on dielectrics (SOD) film formed by spin coat. Low dielectric constant film can also be formed by chemical vapor deposition (CVD), and an example of inorganic low dielectric constant film formed by CVD is fluoridated silicon dioxide film.

The above-described inorganic films and silicon dioxide films can be made porous to further decrease the permittivity.

Examples of organic low dielectric constant film include organic polymer films, such as films of PTFE group, polyamide group, fluoridated polyamide, BCB (benzocyclobutene), parylene-N, parylent-F, MSQ (alkyl silsesquioxane polymer), HOSP (hydrogenated alkyl silsesquioxane polymer). Examples of organic low dielectric constant film formed by CVD include fluoridated carbon films, diamond-like carbon (DLC) films, SiCO films, and SiCO(H) films.

These organic films can also be formed as porous films to further decrease the permittivity.

To realize the advantageous applicability to the low dielectric constant film, non-plasma-activated source gas without containing reactive species (ions and radicals) is used in the step of forming the first diffusion barrier film 2 shown in FIG. 1A, so as not to damage the dielectric film 1.

In the subsequent step shown in FIG. 1B, plasma-activated NH₃ gas is used as the second source gas. The NH₃ gas is plasma-activated to promote the dissociation and promote the reaction with TiCl₄. Consequently, impurities, such as residual chlorine, in the fabricated TiN film membrane decrease, and a TiN film with satisfactory film quality and lower electric resistance can be fabricated.

Since the dielectric film 1 is covered with the first Cu-diffusion barrier film 2, the dielectric film 1 is not subjected to damage due to ions or radicals existing in the plasma-activated gas.

In this manner, in Example 1, by forming a layered Cu-diffusion barrier film consisting of the first Cu-diffusion barrier film 2 and the second Cu-diffusion barrier film 3, a high-quality TiN film (Cu-diffusion barrier film) with less impurities can be formed without damaging the underlying dielectric film 1.

In Example 1, gases other than TiCl₄ may be used as the first source gas. Similarly, gases other than NH₃ and plasma-activated NH₃ may be used as the second source gas.

Using the same process, other types of Cu-diffusion barrier film can be fabricated. For example, TaN film, Ta/TaN layered film, WN film, W/WN layered film, Ti(C)N film, Ta(C)N film, W(C)N film, or W/W(C)N layered film can be formed, achieving the same effect as fabrication of TiN film, which effect is described in detail below. Ti(C)N film is a film containing carbon (C) as an impurity in a TiN film, and is fabricated when forming a film containing titanium nitride (TiN) using a metal-organic gas. Ta(C)N film is a film containing carbon as an impurity in a TaN film and is fabricated when forming a film containing tantalum nitride (TaN) using a metal-organic gas. W(C)N film is a film containing carbon (C) as an impurity in a WN film and is fabricated when forming a film containing tungsten nitride (WN) using a metal-organic gas.

### Example 2

Next, Example 2 is explained based on fabrication of a high-quality Cu-diffusion barrier film over a copper (Cu) film, without damaging the surface of the underlying copper film.

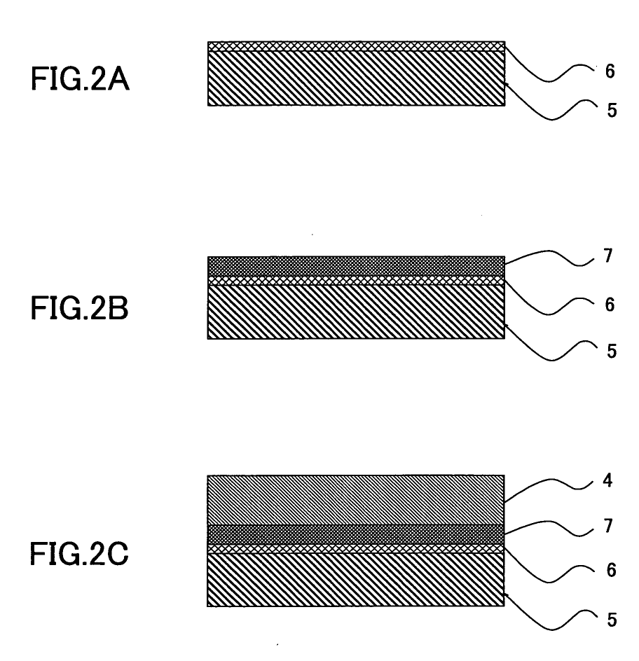

FIG. 2A through FIG. 2C illustrate a film fabrication process of Example 2, where a TiN/Ti(C)N film is formed as the Cu-diffusion barrier film. In FIG. 2A, a first Cu-diffusion barrier film 6 consisting of Ti(C)N is formed over a Cu film 5 formed on the substrate (not shown) by supplying a first source gas and a second source gas alternately onto the substrate to be processed. In this example, the first source gas is TEMAT (Ti[N(C₂H₅CH₃)]₄), and the second source gas is NH₃ gas.

Then, in FIG. 2B, a second Cu-diffusion barrier film 7 consisting of titanium nitride (TiN) is formed over the first Cu-diffusion barrier film 6 by supplying a third source gas and a fourth source gas alternately onto the substrate to be processed. In this second step, the third source gas is TiCl₄ gas, and the fourth source gas is NH₃ gas.

Then, in FIG. 2C, a copper (Cu) film 4 is formed over the second Cu-diffusion barrier film 7 by PVD, CVD, or plating.

In Example 2, a metal-organic gas TEMAT is used in place of a halogen compound gas in the first step shown in FIG. 2A. Accordingly, the underlying copper (Cu) film 5 is not damaged during the formation of the first Cu-diffusion barrier film 6. If a halogen compound gas, such as TiCl₄ gas, is used, the underlying copper (Cu) film 5 corrodes due to existence of halogen (chlorine (Cl) in this case). Examples of the halogen compound gas include TiF₄, TiBr₄, and TiI₄, other than TiCl₄.

It is preferable to use a metal-organic compound not containing halogen, such as metal polyamide compounds or metal carboxyl compounds, which compounds prevent corrosion of the underlying copper (Cu) film 5. The underlying film is not limited to copper, and the same anti-corrosion effect can be achieved with respect to tungsten (W) film and aluminum (Al) film.

In the second step shown in FIG. 2B, a halogen group gas, TiCl₄, is used for the purpose of maintaining the electric resistance of the TiN film low, while preventing organic materials, such as carbon (C) or CHx, from being incorporated as impurities. Since the underlying copper (Cu) film 5 is covered by the first Cu-diffusion barrier film 6 consisting of Ti(C)N, the copper film 5 is not damaged by halogen contained in the source gas during the formation of TiN film as the second Cu-diffusion barrier film 7.

Thus, in Example 2, a high-quality Cu-diffusion barrier film with a TiN/Ti(C)N layered structure can be formed, without damaging the underlying copper (Cu) film 5, while preventing impurities from mixing into the diffusion barrier film.

In Example 2, gases other than TEMAT and TiCl₄ may be used as the first source gas and the third source gas, respectively. Similarly, gases other than NH₃ may be used as the second and fourth source gases. Using the same process, other types of Cu-diffusion barrier film can be fabricated. For example, TaN/Ta(C)N film, Ta/Ta(C)N layered film, WN/W(C)N layered film, or W/W(C)N layered film can be formed, achieving the same effect as fabrication of TiN/Ti(C)N film, which effect is described in detail below.

The second source gas and the fourth source gas used in steps shown in FIG. 2A and FIG. 2B, respectively, may be plasma-activated. In this case, the dissociation of the source gas is promoted, and the reaction for forming the Cu-diffusion barrier film is promoted, while maintaining the impurities contained in the film low. Consequently, electric resistance of the Cu-diffusion barrier film is maintained low.

In addition, in the first step of fabricating the first Cu-diffusion barrier film 6 shown in FIG. 2A, non-plasma-activated second source gas may be used, while plasma-activated fourth source gas may be used to form the second Cu-diffusion barrier film 7 in the second step shown in FIG. 2B, as illustrated in Example 3. This arrangement can achieve film fabrication without damaging either the underlying Cu film or the dielectric film.

The underlying film is not limited to copper, and the same damage preventing effect can be achieved with respect to tungsten (W) film and aluminum (Al) film.

### Example 3

In Example 3, fabrication of a high-quality Cu-diffusion barrier film under the situation where both a Cu film and a dielectric film exist in the underlying layer is explained. In this case, a high-quality Cu-diffusion barrier film is formed without damaging the underlying dielectric film or the underlying Cu layer.

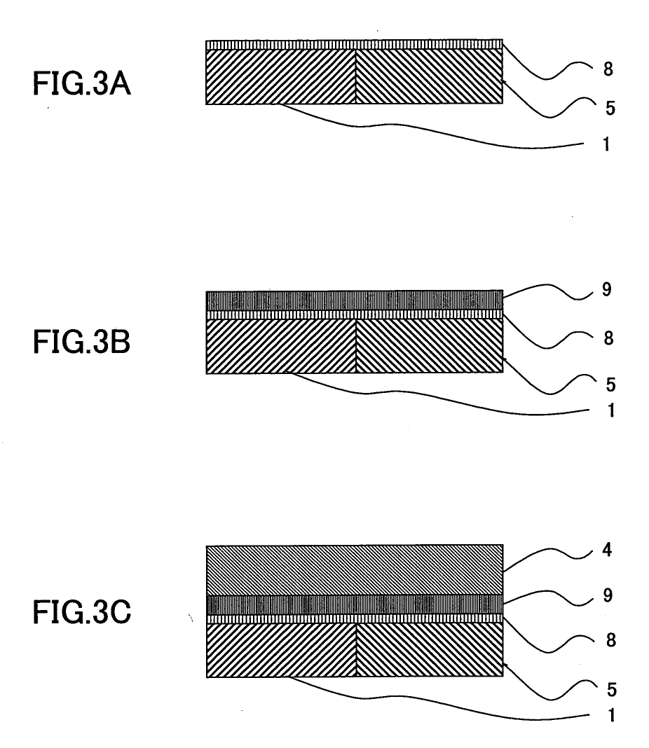

FIG. 3A through FIG. 3C illustrate a fabrication process of the Cu-diffusion barrier film of Example 3, which is formed as a TiN/Ti(C)N layer.

In FIG. 3A, a first Cu-diffusion barrier film 8, which is a Ti(C)N film, is formed over the dielectric film 1 and the Cu film 5 deposited on the substrate, by alternately supplying the first source gas TEMAT and the second source gas NH₃.

Then, in FIG. 3B, a second Cu-diffusion barrier film 9, which is a TiN film, is deposited over the first Cu-diffusion barrier film 8 by alternately supplying TiCl₄ gas (the first source gas) and plasma-activated NH₃ gas (the second source gas).

Then, in FIG. 3C, a Cu film 4 is formed over the second Cu-diffusion barrier film 9 by a PVD method, a CVD method, or plating.

In Example 3, non-plasma-activated NH₃ gas is used as the second source gas in the first step shown in FIG. 3A. This means that the second source gas does not contain damaging species, such as ions or radicals, disadvantageous to the dielectric film 1. As in Example 1, not using a plasma-activated source gas for the first Cu-diffusion barrier film can prevent the dielectric film from being etched by the reacting species, such as N radicals, H radicals, NH radicals, or NH₃ radicals, and prevent physical etching due to ion impact on the dielectric film under plasma excitation of NH₃ gas.

In contrast, a plasma-activated NH₃ gas is used to form the second Cu-diffusion barrier film in the second step shown in FIG. 3B, for the purpose of pushing ahead dissociation to promote reaction with TiCL₄. Consequently, impurities, such as residual chlorine, remaining in the TiN film can be reduced, and a high-quality TiN film with less electric resistance can be formed. The resistance of the resultant TiN/Ti(C)N barrier film for preventing copper (Cu) diffusion can be reduced as a whole. Since the dielectric film 1 is covered with the first Cu-diffusion barrier film 2, it is not damaged by ions or radicals in the plasma-activated gas.

In the first step for forming the first Cu-diffusion barrier film shown in FIG. 3A, TEMAT, which is a metal-organic gas, is used as the first source gas to prevent damage to the underlying Cu film 5 by halogen.

In contrast, TiCl₄, which is a halogen compound gas, is used as the first source gas in the second step for forming the second Cu-diffusion barrier film shown in FIG. 3B, for the purpose of preventing impurities, such as carbon (C) or CHx, from being taken into the TiN film. Consequently, the resistance of the resultant TiN/Ti(C)N barrier film for preventing copper (Cu) diffusion can be reduced as a whole. Since the underlying Cu film 5 is covered with the first Cu-diffusion barrier film 8, it is not damaged by halogen contained in the first source gas.

In conclusion, a high-quality Cu-diffusion barrier film (TiN/Ti(C)N) with less impurity content can be formed without damaging the underlying dielectric film 1 or Cu film 5.

Any suitable gas, other than TEMAT and TiCl₄, can be used as the first source gas. Similarly, any suitable gas, other than NH₃, can be used as the second source gas. The Cu-diffusion barrier film is not limited to the TiN/Ti(C)N film, but any suitable combination, such as TaN/Ta(C)N film, Ta/Ta(C)N layered film, WN/W(C)N film, or W/W(C)N layered film, may be formed. These films have the same advantages as the TiN/Ti(C)N film in this embodiment.

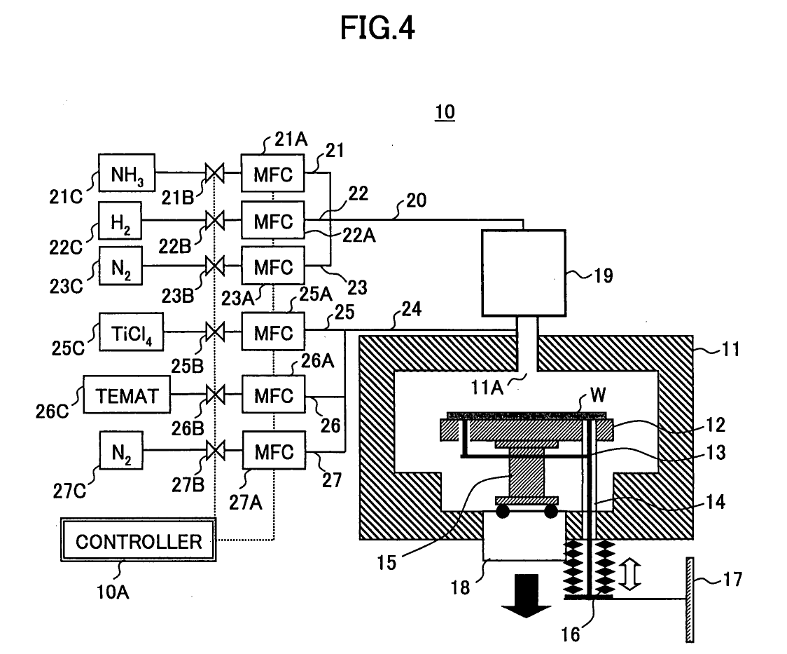

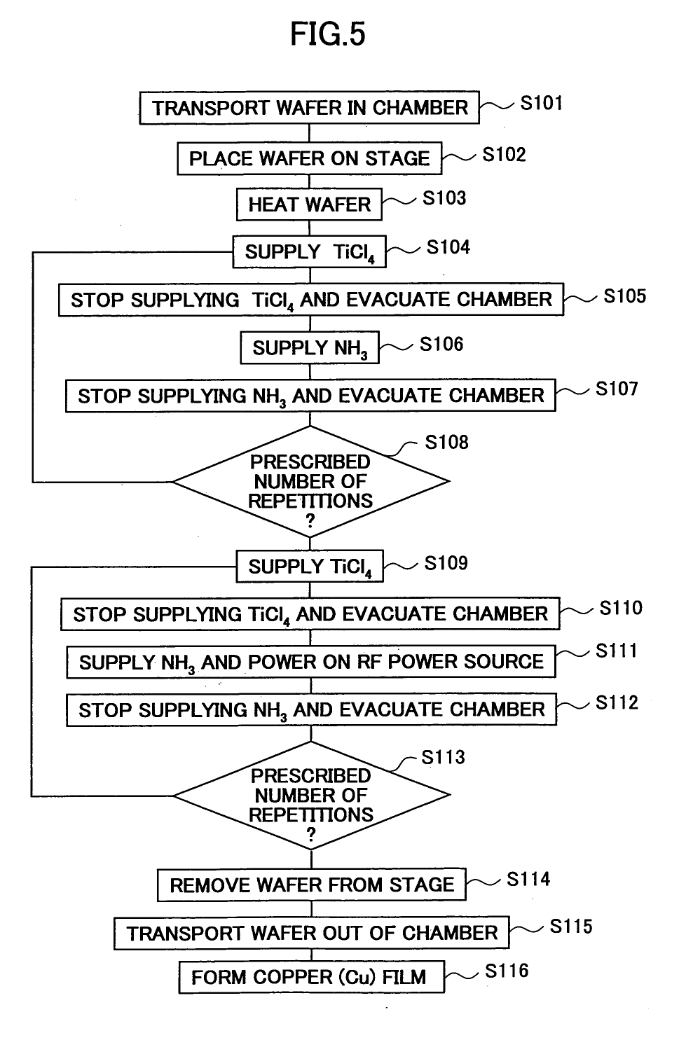

Next, explanation is made of a film deposition apparatus used to form the Cu-diffusion films illustrated in Examples 1 through 3, in conjunction with FIG. 4.

### Example 4

FIG. 4 is a schematic diagram illustrating an example of the film deposition apparatus 10 used for film formation of Examples 1 through 3. The film deposition apparatus 10 includes a processing chamber 11 made of, for example, aluminum, surface-treated (alumite treated) aluminum, or stainless steel. A wafer stage 12 made of aluminum nitride (AlN) and for holding a substrate is supported on a base 15 in the processing chamber 11. A semiconductor wafer W is placed on the center of the wafer stage 12. A heater (not shown) is provided inside the wafer stage 12 to heat the wafer W to a desired temperature.

The processing chamber 11 is evacuated by an evacuation system (not shown) connected to the evacuation port 18 so as to maintain the chamber under reduced pressure. The wafer W to be processed is transported into or out of the processing chamber 11 through a gate valve (not shown).

A lifter pin 13 is provided to the wafer stage 12 in order to allow the wafer W to be mounted on or removed from the wafer stage 12 when the wafer W is transferred into or out of the processing chamber 11. The lifter pin 13 is coupled, via a coupling rod 14 vacuum-sealed with a bellows 16, to the up/down driving mechanism 17. By bringing up or down the lifter pin 13, the wafer W is mounted on or lifted from the wafer stage 12.

The processing chamber 11 is furnished with a gas supply port 11A, through which source gases or diluting gases required for film formation are introduced into the chamber 11.

A gas supply line 24 extends from the gas supply port 11A for supplying the first source gas and the first diluting gas into the processing chamber 11. The gas supply line 24 is connected to a halogen compound gas supply line 25 and a metal-organic gas supply line 26, through which the first source gases are to be supplied, respectively, as well as to a diluting gas supply line 27.

The halogen compound gas supply line 25 is connected, via a mass flow controller 25A and a valve 25B, to the first source gas supply 25C for supplying halogen compound gas. The first source gas supply 25C has a halogen compound gas supply source containing titanium (Ti), tantalum (Ta), or tungsten (W) in order to supply the halogen compound gas containing Ti, Ta, or W, as the first source gas, to the processing chamber 11.

The metal-organic gas supply line 26 is connected, via a mass flow controller 26A and a valve 26B, to another first source gas supply 26C for supplying a metal-organic gas. The first source gas supply 26C has a metal-organic gas supply source containing titanium (Ti), tantalum (Ta), or tungsten (W) in order to supply the metal-organic gas containing Ti, Ta, or W, as the first source gas, to the processing chamber 11.

The diluting gas supply line 27 is connected to a diluting gas supply 27C via a mass flow controller 27A and a valve 27B. The diluting gas supply 27C has a diluting gas supply source for supplying a diluting gas, such as nitrogen (N₂), argon (Ar), or helium (He), via the gas supply line 24 to the processing chamber 11 to dilute the first source gas. Supplying the diluting gas through the gas supply line 24 is advantageous in preventing back-flow of the gases from the processing chamber 11 back to the gas supply line 24.

A second gas supply line 20 also extends from the gas supply port 11A via a remote plasma source 19, which is explained below. The second gas supply line 20 is connected to a nitride gas supply line 21 and a hydrogen gas supply line 22, through which the second sources gases are to be supplied, as well as to a diluting gas supply line 23. The nitrogen gas supply line 21 is connected, via a mass flow controller 21A and a valve 21B, to the second source gas supply 21C for supplying nitride gas. The second source gas supply 21C has a nitride gas supply source for supplying a nitrogen compound, such as NH₃, N₂H₄, NH(CH₃)₂, N₂H₃CH₃, to the processing chamber 11.

The hydrogen gas supply line 22 is connected, via a mass flow controller 26A and a valve 26B, to another second source gas supply 26C for supplying a metal-organic gas. The second source gas supply 22C has a reducing gas supply source, such as hydrogen (H₂) gas supply source, to supply the hydrogen gas, for example, to the processing chamber 11.

The diluting gas supply line 23 is connected to a diluting gas supply 23C via a mass flow controller 23A and a valve 23B. The diluting gas supply 23C supplies a diluting gas, such as nitrogen (N2), argon (Ar), or helium (He), via the second gas supply line 20 to the processing chamber 11 to dilute the second source gas. Supplying the diluting gas through the gas supply line 20 is advantageous in preventing back-flow of the gases from the processing chamber 11 back to the remote plasma source 19 or to the gas supply line 20.

The remote plasma source 19 has a plasma generating apparatus, to which apparatus RF power is applied to excite the gases into plasma. For example, the remote plasma source 19 excites the nitrogen source gas or the hydrogen source gas supplied to the remote plasma source 19, into the plasma, as necessary. If plasma excitation is not performed, the gas passes through the remote plasma source 19, as it is, and is supplied to the processing chamber 11. Under plasma excitation, reacting species, such as ions radicals, are generated by gas dissociation, which species are supplied to the processing chamber 11 through the gas supply port 11A. For example, if the second source gas is plasma-excited, NHₓ* (radicals), H* (radicals), or N* (radicals) are supplied into the processing chamber 11.

In this embodiment, the plasma excitation is performed using an ICP (induced coupling plasma) source of high-frequency waves at 2 MHz. However, the invention is not limited to this method, and, for example, parallel plate plasma excitation or ECR plasma excitation may be used. In addition, another exciting frequency, such as 13.56 MHz high-frequency waves or microwaves (at 2.45 GHz) may be employed. As long as the supplied gas is dissociated through plasma excitation, any suitable frequency and excitation method can be employed.

The operations of the film deposition apparatus 10, including opening and closing of the valves 21B through 27B, the motion of the lifter pin 13, and the plasma excitation in the remote plasma source 19, are comprehensively controlled by the controller 10A.

Next, detailed operations of the film deposition apparatus 10 for forming the films as illustrated in Examples 1 through 3 are explained below.

### Example 5

FIG. 5 is a flowchart showing the process flow of the film deposition apparatus 10 when forming the Cu-diffusion barrier film of Example 1 shown in FIG. 1. In this example, TiN film is formed as the Cu-diffusion barrier film over an oxidation film, which is an underlying layer formed on the substrate.

In step S101, the wafer W to be processed is transferred into the film deposition apparatus 10.

Then, in step S102, the wafer W is placed onto the wafer stage 12.

Then, in step S103, the wafer W is heated by the heater set inside the wafer stage 12, and is maintained at about 400° C. in this step and the subsequent steps.

Then, in step S104, the valve 25B is opened to supply TiCl₄ (the first source gas) into the processing chamber 11 at gas flow rate of 30 sccm under the control of the mass flow controller 25A. Simultaneously, the valves 27B and 23B are also opened to supply N₂ gas as the diluting gas to the processing chamber 11, through diluting gas supply lines 27 and 23, at 100 sccm each under the control of mass flow controllers 27A and 23A, respectively. Accordingly, the total of 200 sccm N₂ gas is supplied to the processing chamber 11. The TiCl₄ gas is supplied onto the wafer W, and is adsorbed onto the dielectric (oxide) film 1.

Then, in step S105, the valves 23B, 25B and 27B are closed to stop the gas supply of TiCl₄ and N₂ into the processing chamber 11. The residual TiCl₄ remaining in the processing chamber 11, without being adsorbed onto the dielectric film 1, is purged from the evacuation port 18.

Then, in step S106, the valve 21B is opened to introduce NH₃ into the processing chamber 11 at 800 sccm under the control of mass flow controller 21A. Simultaneously, the valves 27B and 23B are opened to supply N₂ gas as the diluting gas to the processing chamber 11, through diluting gas supply lines 27 and 23, at 100 sccm each under the control of mass flow controllers 27A and 23A, respectively. Accordingly, the total of 200 sccm N₂ gas is supplied to the processing chamber 11. The NH₃ gas is supplied onto the wafer W, and is reacted with the TiCl₄ adsorbed onto the dielectric (oxide) film 1 to form TiN.

Then, in step S107, the valves 21B, 23B and 27B are closed to stop gas supply of NH₃ and N₂ to the processing chamber 11. The unreacted NH₃ remaining in the processing chamber 11 is purged from the evacuation port 18.

Then, in step S108, the process returns to step S104 to repeat steps S104 through S107 until a desired thickness of TiN film is obtained. After the necessary number of repetitions, the process proceeds to step S109. Since non-plasma-excited NH₃ gas is used as the second source gas, damaging species, such as ions or radicals, does not exist in the source gas, and therefore, the underlying dielectric film 1 is not damaged.

The subsequent steps S109 and S110 are the same as steps S104 and S105.

Then, in step S111, the valve 21B is opened to supply NH₃ at 400 sccm under the control of mass flow controller 21A. Simultaneously, the valves 27B and 23B are opened to supply N₂ gas as the diluting gas to the processing chamber 11, through diluting gas supply lines 27 and 23, at 100 sccm each under the control of mass flow controllers 27A and 23A, respectively. Accordingly, the total of 200 sccm N₂ gas is supplied to the processing chamber 11. In this step, high-frequency power of 400 W is applied to the remote plasma source 19 to perform plasma excitation. The supplied NH₃ is dissociated into NHx*, which is then supplied to the processing chamber 11. This NHₓ* reacts with TiCl₄ adsorbed onto the previously formed TiN film 2., and an additional TiN film 3 is formed. In this case, NHₓ*, is used for the reaction in place of NH₃, and therefore, the reaction with TiCl4 is promoted to form the TiN film promptly. Consequently, impurities, such as residual chlorine, contained in the resultant TiN film can be reduced, and high film quality is realized.

Then, in step S112, application of high-frequency power to the remote plasma source is stopped, and the valves 21B, 23B and 27B are closed to stop gas supply of NH₃ and N₂ to the processing chamber 11. The unreacted NH₃ remaining in the processing chamber 11 is purged from the evacuation port 18.

Then, in step S113, the process returns to step S109 to repeat steps S109 through S112 until a desired thickness of the second Cu-diffusion barrier film 3 is obtained. After the necessary number of repetitions, the process proceeds to step S114.

In step S114, the lifter pin 13 is elevated to remove the wafer W from the wafer stage 12.

In step S115, the wafer W is transported out of the processing chamber 11.

In step S116, the wafer W is transported to a Cu-film deposition apparatus, such as a PVD apparatus, a CVD apparatus, or a plating apparatus, to form copper (Cu) film 4 over the second Cu-diffusion barrier film 3.

In this flow, TiCl₄ is used as the first source gas, which gas is introduced in steps S104 through S109. When forming the first Cu-diffusion barrier film 2, NH₃ is introduced as the second source gas in step S106, while plasma-activated NH₃ is introduced as the second source gas when forming the second Cu-diffusion barrier film 4, to form the double layered TiN film. However, the invention is not limited to this example.

Table 1 illustrates examples of the first and second source gases used to form the first Cu-diffusion barrier film, as well as examples of the first and second source gases used to form the second Cu-diffusion barrier film, when the TiN barrier film shown in FIG. 1 is formed using a halogen compound gas as the first source gas.

TABLE 1

| | FIRST SOURCE GAS | SECOND SOURCE GAS |
|---|---|---|
| 1^{st} Cu-DIFFUSION | TiCl₄ | NH₃ |
| BARRIER FILM | TiF₄ | N₂H₄ |
| | TiBr₄ | NH(CH₃)₂ |
| | TiI₄ | N₂H₃CH₃ |
| 2^{nd} Cu-DIFFUSION | TiCl₄ | NHx* |
| BARRIER FILM | TiF₄ | (plasma-activated NH₃, |
| | TiBr₄ | or plasma-activated |
| | TiI₄ | N₂/H₂ mixed gas) |

Table 2 illustrates examples of the first and second source gases used to form the first Cu-diffusion barrier film, as well as examples of the first and second source gases used to form the second Cu-diffusion barrier film, when tantalum nitride (TaN) barrier films are formed using a halogen compound gas as the first source gas. By using the source gases listed in Table 2, TaN films can be formed in a process similar to the process described above. It should be noted that if plasma-activated H² gas (H⁺/H*) is used as the second source gas to form the second Cu-diffusion barrier film, a Ta/TaN film is formed, which film can achieve the same effect as that illustrated above.

TABLE 2

| | FIRST SOURCE GAS | SECOND SOURCE GAS |
|---|---|---|
| 1^{st} Cu-DIFFUSION | TaF₅ | NH₃ |
| BARRIER FILM | TaCl₅ | N₂H₄ |
| | TaBr₅ | NH(CH₃)₂ |
| | TaI₅ | N₂H₃CH₃ |
| 2^{nd} Cu-DIFFUSION | TaF₅ | NHx* (plasma-activated |
| BARRIER FILM | TaCl₅ | NH₃, or plasma- |
| | TaBr₅ | activated N₂/H₂ mixed |
| | TaI₅ | gas); |
| | | H⁺/H* (plasma- |
| | | activated H₂ gas) |

Table 3 illustrates examples of the first and second source gases used to form the first Cu-diffusion barrier film, as well as examples of the first and second source gases used to form the second Cu-diffusion barrier film, when tungsten nitride (WN) barrier films are formed using a halogen compound gas as the first source gas. By using the source gases listed in Table 3, WN film can be formed in a process similar to the process described above. It should be noted that if plasma-activated H₂ gas (H⁺/H*) is used as the second source gas to form the second Cu-diffusion barrier film, a W/WN film is formed, which film can achieve the same effect as that illustrated above.

TABLE 3

| | FIRST SOURCE GAS | SECOND SOURCE GAS |
|---|---|---|
| 1^{st} Cu-DIFFUSION | WF₆ | NH₃ |
| BARRIER FILM | | N₂H₄ |
| | | NH(CH₃)₂ |
| | | N₂H₃CH₃ |
| 2^{nd} Cu-DIFFUSION | WF₆ | NHx* (plasma-activated |
| BARRIER FILM | | NH₃, or plasma- |
| | | activated N₂/H₂ mixed |
| | | gas); |
| | | H⁺/H* (plasma- |
| | | activated H₂ gas) |

Table 4 illustrates examples of the first and second source gases used to form the first Cu-diffusion barrier film, as well as examples of the first and second source gases used to form the second Cu-diffusion barrier film, when Ti(C)N barrier films are formed using a metal-organic gas as the first source gas. By using the source gases listed in Table 4, a Ti(C)N film can be formed in a process similar to the process described above.

TABLE 4

| | | SECOND SOURCE |
|---|---|---|
| | FIRST SOURCE GAS | GAS |
| 1^{st} Cu- | Ti[N(C₂H₅CH₃)]₄ (TEMAT) | NH₃ |
| DIFFUSION | Ti[N(CH₃)₂]₄ (TDMAT) | N₂H₄ |
| BARRIER FILM | Ti[N(C₂H₅)₂]₄ (TDEAT) | NH(CH₃)₂ |
| | | N₂H₃CH₃ |
| 2^{nd} Cu- | Ti[N(C₂H₅CH₃)]₄ (TEMAT) | NHx* (plasma- |
| DIFFUSION | Ti[N(CH₃)₂]₄ (TDMAT) | activated NH₃, or |
| BARRIER FILM | Ti[N(C₂H₅)₂]₄ (TDEAT) | plasma-activated |
| | | N₂/H₂ mixed gas); |
| | | H⁺/H* (plasma- |
| | | activated H₂ gas) |

Table 5 illustrates examples of the first and second source gases used to form the first Cu-diffusion barrier film, as well as examples of the first and second source gases used to form the second Cu-diffusion barrier film, when Ta(C)N barrier films are formed using a metal-organic gas as the first source gas. By using the source gases listed in Table 5, a Ta(C)N film can be formed in a process similar to the process described above.

TABLE 5

| | | SECOND SOURCE |
|---|---|---|
| | FIRST SOURCE GAS | GAS |
| 1^{st} Cu- | Ta[N(C₂H₅CH₃)]₅ (PEMAT) | NH₃ |
| DIFFUSION | Ta[N(CH₃)₂]₅ (PDMAT) | N₂H₄ |
| BARRIER FILM | Ta[N(C₂H₅)₂]₅ (PDEAT) | NH(CH₃)₂ |
| | Ta(NC(CH₃)₃)(N(C₂H₅)₂)₃ | N₂H₃CH₃ |
| | (TBTDETT) | |
| | Ta(NC₂H₅)(N(C₂H₅)₂)₃ | |
| | Ta(NC(CH₃)₂C₂H₅)(N(CH₃)₂)₃ | |
| | Ta(NC(CH₃)₃)(N(CH₃)₂)₃ | |
| 2^{nd} Cu- | Ta[N(C₂H₅CH₃)]₅ (PEMAT) | NHx* (plasma- |
| DIFFUSION | Ta[N(CH₃)₂]₅ (PDMAT) | activated NH₃, |
| BARRIER FILM | Ta[N(C₂H₅)₂]₅ (PDEAT) | or plasma- |
| | Ta(NC(CH₃)₃)(N(C₂H₅)₂)₃ | activated N₂/H₂ |
| | (TBTDETT) | mixed gas); |
| | Ta(NC₂H₅)(N(C₂H₅)₂)₃ | H⁺/H* (plasma- |
| | Ta(NC(CH₃)₂C₂H₅)(N(CH₃)₂)₃ | activated H₂ |
| | | gas) |

Table 6 illustrates examples of the first and second source gases used to form the first Cu-diffusion barrier film, as well as example of the first and second source gases used to form the second Cu-diffusion barrier film, when W(C)N barrier films are formed using a metal-organic gas as the first source gas. By using the source gases listed in Table 6, a W(C)N film can be formed in a process similar to the process described above. It should be noted that if plasma-activated H₂ gas (H⁺/H*) is used as the second source gas to form the second Cu-diffusion barrier film, a W(C)/W(C)N film is formed, which film can achieve the same effect as that illustrated above.

TABLE 6

| | FIRST SOURCE GAS | SECOND SOURCE GAS |
|---|---|---|
| 1^{st} Cu-DIFFUSION | W(CO)₆ | NH₃ |
| BARRIER FILM | | N₂H₄ |
| | | NH(CH₃)₂ |
| | | N₂H₃CH₃ |
| 2^{nd} Cu-DIFFUSION | W(CO)₆ | NHx* (plasma-activated |
| BARRIER FILM | | NH₃, or plasma- |
| | | activated N₂/H₂ mixed |
| | | gas); |
| | | H⁺/H* (plasma- |
| | | activated H₂ gas) |

### Example 6

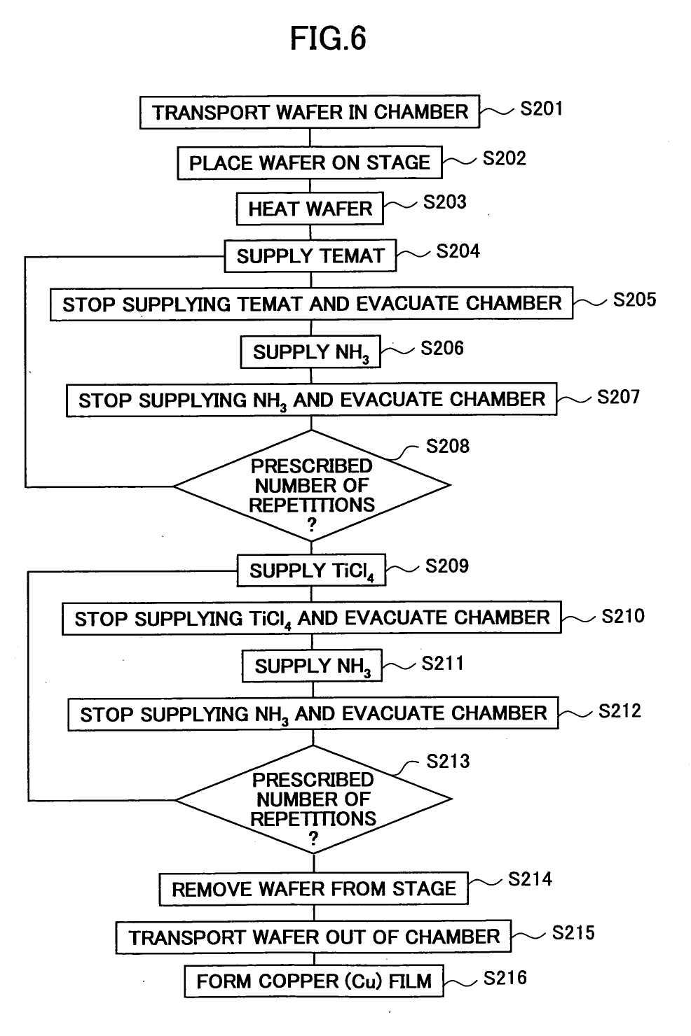

FIG. 6 is a flowchart showing a film formation process of the Cu-diffusion barrier film shown in FIG. 2, without damaging the underlying copper (Cu) film. The same components and steps as those illustrated in the previous examples are denoted by the same symbols, and explanation for them is omitted.

Steps S201 through S203 and steps S214 through S216 are the same as steps S101 through S103 and steps S114 through S116, respectively, illustrated in FIG. 5.

In step S204, the valve 26B is opened to supply TEMAT (which is the first source gas) into the processing chamber 11 at gas flow rate of 30 sccm under the control of the mass flow controller 26A. Simultaneously, the valves 27B and 23B are also opened to supply N₂ gas as the diluting gas to the processing chamber 11, through diluting gas supply lines 27 and 23, at 100 sccm each under the control of mass flow controllers 27A and 23A, respectively. Accordingly, the total of 200 sccm N₂ gas is supplied to the processing chamber 11. The first source gas TEMAT is supplied onto the wafer W, and is adsorbed onto the copper (Cu) film 5 formed over the wafer W.

Then, in step S205, the valves 23B, 26B and 27B are closed to stop the gas supply of TEMAT and N₂ into the processing chamber 11. The residual TEMAT remaining in the processing chamber 11, without being adsorbed onto the copper (Cu) film 5, is purged from the evacuation port 18.

Then, in step S206, the valve 21B is opened to introduce NH₃ into the processing chamber 11 at 800 sccm under the control of mass flow controller 21A. Simultaneously, the valves 27B and 23B are opened to supply N₂ gas as the diluting gas to the processing chamber 11, through diluting gas supply lines 27 and 23, at 100 sccm each under the control of mass flow controllers 27A and 23A, respectively. Accordingly, the total of 200 sccm N₂ gas is supplied to the processing chamber 11. The NH₃ gas is supplied onto the wafer W, which has been heated up to about 400° C., and is reacted with the TEMAT adsorbed onto the wafer W.

Then, in step S207, the valves 21B, 23B and 27B are closed to stop gas supply of NH₃ and N₂ to the processing chamber 11. The unreacted NH₃ remaining in the processing chamber 11 is purged from the evacuation port 18.

Then, in step S208, the process returns to step S204 to repeat steps S204 through S207 until a desired thickness of Ti(C)N film 6 is obtained. After the necessary number of repetitions, the process proceeds to step S209.

Then, in steps S209 through S212, the second Cu-diffusion barrier film 7 is formed. As the second Cu-diffusion barrier film 7, TiN film is formed using TiCl₄ as the first source gas. Steps S209 through S212 are the same steps S104 through S107 shown in FIG. 5.

In step S213, the process returns to step S209 to repeat steps S209 through S212 until a desired thickness of the second Cu-diffusion barrier film 7 is obtained. After the necessary number of repetitions, the process proceeds to step S214.

In Example 6, a metal-organic gas is used as the first source gas (step S204) to form the first Cu-diffusion barrier film Ti(C)N, while a halogen compound gas is used as the first source gas (step S209) to form the second Cu-diffusion barrier film (TiN). With this arrangement, the underlying copper (Cu) film 5 is prevented from corroding due to the halogen. Consequently, a Cu-diffusion barrier film with less impurity content and lower electric resistance can be obtained.

In Example, 6, the first source gas used in step S204 is TEMAT as an example of the metal-organic gas, the first source gas used in step S209 is TiCl₄ as an example of the halogen compound gas, and the second source gas used in steps S206 and S211 is NH₃. However, the invention is not limited to this example.

Table 7 illustrates examples of the first and second source gases used to form the first Cu-diffusion barrier film 6, as well as examples of the first and second source gases used to form the second Cu-diffusion barrier film 7, when fabricating the TiN/Ti(C)N layered film. Any combination of these gases can achieve the same effect as that illustrated in the above-described example.

TABLE 7

| | FIRST SOURCE GAS | SECOND SOURCE GAS |
|---|---|---|
| 1^{st} Cu- | Ti[N(C₂H₅CH₃)]₄ (TEMAT) | NH₃ |
| DIFFUSION | Ti[N(CH₃)₂]₄ (TDMAT) | N₂H₄ |
| BARRIER | Ti[N(C₂H₅)₂]₄ (TDEAT) | NH(CH₃)₂ |
| FILM | | N₂H₃CH₃ |
| 2^{nd} Cu- | TiCl₄ | NH₃ |
| DIFFUSION | TiF₄ | N₂H₄ |
| BARRIER | TiBr₄ | NH(CH₃)₂ |
| FILM | TiI₄ | N₂H₃CH₃ |

Table 8 illustrates examples of the first and second source gases used to form the first Cu-diffusion barrier film, as well as examples of the first and second source gases used to form the second Cu-diffusion barrier film, when a TaN/Ta(C)N layered film is formed. By using the source gases listed in Table 8, the above-described effect can be achieved.

TABLE 8

| | | SECOND SOURCE |
|---|---|---|
| | FIRST SOURCE GAS | GAS |
| 1^{st} Cu- | Ta[N(C₂H₅CH₃)]₅ (PEMAT) | NH₃ |
| DIFFUSION | Ta[N(CH₃)₂]₅ (PDMAT) | N₂H₄ |
| BARRIER FILM | Ta[N(C₂H₅)₂]₅ (PDEAT) | NH(CH₃)₂ |
| | Ta(NC(CH₃)₃)(N(C₂H₅)₂)₃ | N₂H₃CH₃ |
| | (TBTDETT) | |
| | Ta(NC₂H₅)(N(C₂H₅)₂)₃ | |
| | Ta(NC(CH₃)₂C₂H₅)(N(CH₃)₂)₃ | |
| | Ta(NC(CH₃)₃)(N(CH₃)₂)₃ | |
| 2^{nd} Cu- | TaF₅ | NH₃ |
| DIFFUSION | TaCl₅ | N₂H₄ |
| BARRIER FILM | TaBr₅ | NH(CH₃)₂ |
| | TaI₅ | N₂H₃CH₃ |

Table 9 illustrates examples of the first and second source gases used to form the first Cu-diffusion barrier film, as well as examples of the first and second source gases used to form the second Cu-diffusion barrier film, when a WN/W(C)N layered film is formed. By using the source gases listed in Table 9, the above-described effect can be achieved.

TABLE 9

| | FIRST SOURCE GAS | SECOND SOURCE GAS |
|---|---|---|
| 1^{st} Cu-DIFFUSION | W(CO)₆ | NH₃ |
| BARRIER FILM | | N₂H₄ |
| | | NH(CH₃)₂ |
| | | N₂H₃CH₃ |
| 2^{nd} Cu-DIFFUSION | WF₆ | NH₃ |
| BARRIER FILM | | N₂H₄ |
| | | NH(CH₃)₂ |
| | | N₂H₃CH₃ |

In Example 6, the second source gas may be plasma-activated in steps S206 and S211, as in Example 2. In this case, dissociation of the second source gas is promoted, and the reaction for forming the Cu-diffusion barrier film is advanced. As a result, the amount of impurities contained in the Cu-diffusion barrier film can be reduced, and the electric resistance is lowered.

Table 10 illustrates examples of the first source gases used to form the first and second Cu-diffusion barrier films, in combination with examples of the plasma-activated second source gases used to form the first and second Cu-diffusion barrier films. By using the source gases listed in Table 10, TiN/Ti(C)N films can be formed, achieving the same effect.

TABLE 10

| | | SECOND SOURCE |
|---|---|---|
| | FIRST SOURCE GAS | GAS |
| 1^{st} Cu- | Ti[N(C₂H₅CH₃)]₄ (TEMAT) | NHx* (plasma- |
| DIFFUSION | Ti[N(CH₃)₂]₄ (TDMAT) | activated NH₃, or |
| BARRIER FILM | Ti[N(C₂H₅)₂]₄ (TDEAT) | plasma-activated |
| | | N₂/H₂ mixed gas); |
| | | H⁺/H* (plasma- |
| | | activated H₂ gas) |
| 2^{nd} Cu- | TiCl₄ | NHx* (plasma- |
| DIFFUSION | TiF₄ | activated NH₃, or |
| BARRIER FILM | TiBr₄ | plasma-activated |
| | TiI₄ | N₂/H₂ mixed gas); |

Table 11 illustrates examples of the combinations of the first and second source gases to form the first and second Cu-diffusion barrier films, respectively, when TaN/Ta(C)N barrier films are formed using a plasma-activated gas as the second source gas. By using the source gases listed in Table 11, TaN/Ta(C)N films can be formed in a process similar to the process described above, achieving the effect of reduced impurity content. It should be noted that if plasma-activated H₂ gas (H⁺/H*) is used as the second source gas to form the second Cu-diffusion barrier film, a Ta/Ta(C)N film is formed, in place of the TaN/Ta(C)N film, which film can achieve the same effect as that illustrated above.

TABLE 11

| | | SECOND |
|---|---|---|
| | FIRST SOURCE GAS | SOURCE GAS |
| 1^{st} Cu- | Ta[N(C₂H₅CH₃)]₅ (PEMAT) | NHx* (plasma- |
| DIFFUSION | Ta[N(CH₃)₂]₅ (PDMAT) | activated NH₃, |
| BARRIER FILM | Ta[N(C₂H₅)₂]₅ (PDEAT) | or plasma- |
| | Ta(NC(CH₃)₃)(N(C₂H₅)₂)₃ | activated N₂/H₂ |
| | (TBTDETT) | mixed gas); |
| | Ta(NC₂H₅)(N(C₂H₅)₂)₃ | H⁺/H* (plasma- |
| | Ta(NC(CH₃)₂C₂H₅)(N(CH₃)₂)₃ | activated H₂ |
| | Ta(NC(CH₃)₃)(N(CH₃)₂)₃ | gas) |
| 2^{nd} Cu- | TaF₅ | NHx* (plasma- |
| DIFFUSION | TaCl₅ | activated NH₃, |
| BARRIER FILM | TaBr₅ | or plasma- |
| | TaI₅ | activated N₂/H₂ |
| | | mixed gas); |
| | | H⁺/H* (plasma- |
| | | activated H₂ gas) |

Table 12 illustrates examples of the combinations of the first and second source gases to form the first and second Cu-diffusion barrier films, respectively, when WN/W(C)N barrier films are formed using a plasma-activated gas as the second source gas. By using the source gases listed in Table 12, WN/W(C)N films can be formed in a process similar to the process described above. It should be noted that if plasma-activated H₂ gas (H⁺/H*) is used as the second source gas to form the second Cu-diffusion barrier film, W/W(C)N film is formed, in place of a the WN/W(C)N film, which film can achieve the same effect.

TABLE 12

| | FIRST SOURCE GAS | SECOND SOURCE GAS |
|---|---|---|
| 1^{st} Cu-DIFFUSION | W(CO)₆ | NHx* (plasma-activated |
| BARRIER FILM | | NH₃, or plasma- |
| | | activated N₂/H₂ |
| | | mixed gas); |
| | | H⁺/H* (plasma- |
| | | activated H₂ gas) |
| 2^{nd} Cu-DIFFUSION | WF₆ | NHx* (plasma-activated |
| BARRIER FILM | | NH₃, or plasma- |
| | | activated N₂/H₂ |
| | | mixed gas); |
| | | H⁺/H* (plasma- |
| | | activated H₂ gas) |

### Example 7

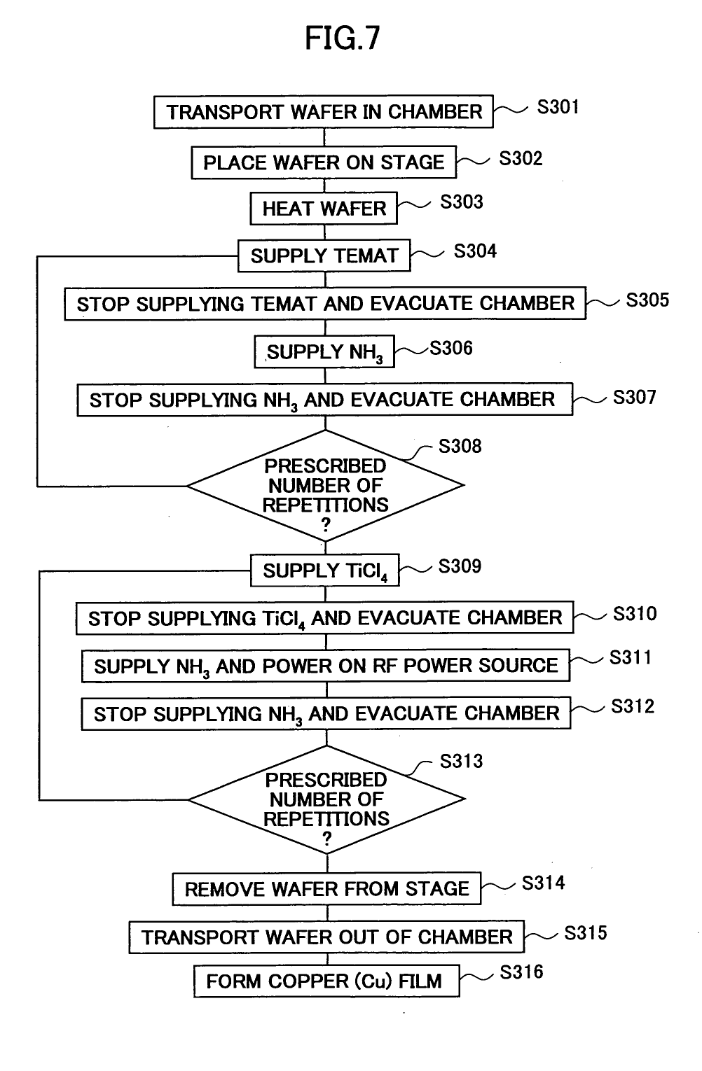

FIG. 7 is a flowchart showing a film formation process of the Cu-diffusion barrier film shown in FIG. 3, without damaging the underlying dielectric film 1 and copper (Cu) film 5. The same components and steps as those illustrated in the previous examples are denoted by the same symbols, and explanation for them is omitted.

Steps S301 through S310 and steps S313 through S316 are the same as steps S201 through S210 and steps S213 through S216, respectively, illustrated in FIG. 6. Steps S311 and S312 are the same as steps S111 and S112 shown in FIG. 5. With this process, a high-quality TiN/Ti(C)N film with less impurity content is formed as the Cu-diffusion barrier film, without damaging the underlying dielectric film or copper film.

The first and second source gases used to form each of the first and second Cu-diffusion barrier films may be changed from those illustrated in the flowchart of FIG. 7, as long as a film similar to the TiN/Ti(C)N film is formed.

Table 13 illustrates examples of the first and second source gases used to form the first Cu-diffusion barrier film 8, as well as examples of the first and second source gases used to form the second Cu-diffusion barrier film 9, when fabricating the TiN/Ti(C)N barrier films. By using these gases, the same effect can be achieved.

TABLE 13

| | FIRST SOURCE GAS | SECOND SOURCE GAS |
|---|---|---|
| 1^{st} Cu- | Ti[N(C₂H₅CH₃)]₄ (TEMAT) | NH₃ |
| DIFFUSION | Ti[N(CH₃)₂]₄ (TDMAT) | N₂H₄ |
| BARRIER | Ti[N(C₂H₅)₂]₄ (TDEAT) | NH(CH₃)₂ |
| FILM | | N₂H₃CH₃ |
| 2^{nd} Cu- | TiCl₄ | NHx* (plasma-activated |
| DIFFUSION | TiF₄ | NH₃, or plasma- |
| BARRIER | TiBr₄ | activated N₂/H₂ mixed |
| FILM | TiI₄ | gas); |

Table 14 illustrates examples of the first and second source gases used to form the first Cu-diffusion barrier film, as well as examples of the first and second source gases used to form the second Cu-diffusion barrier film, when a TaN/Ta(C)N layered film is formed. By using the source gases listed in Table 14, the above-described effect can be achieved. It should be noted that if plasma-activated H₂ gas (H⁺/H*) is used as the second source gas to form the second Cu-diffusion barrier film, a Ta/Ta(C)N film is formed, in place of the TaN/Ta(C)N film, which film can achieve the same effect.

TABLE 14

| | | SECOND SOURCE |
|---|---|---|
| | FIRST SOURCE GAS | GAS |
| 1^{st} Cu- | Ta[N(C₂H₅CH₃)]₅ (PEMAT) | NH₃ |
| DIFFUSION | Ta[N(CH₃)₂]₅ (PDMAT) | N₂H₄ |
| BARRIER FILM | Ta[N(C₂H₅)₂]₅ (PDEAT) | NH(CH₃)₂ |
| | Ta(NC(CH₃)₃)(N(C₂H₅)₂)₃ | N₂H₃CH₃ |
| | (TBTDETT) | |
| | Ta(NC₂H₅)(N(C₂H₅)₂)₃ | |
| | Ta(NC(CH₃)₂C₂H₅)(N(CH₃)₂)₃ | |
| | Ta(NC(CH₃)₃)(N(CH₃)₂)₃ | |
| 2^{nd} Cu- | TaF₅ | NHx* (plasma- |
| DIFFUSION | TaCl₅ | activated NH₃, |
| BARRIER FILM | TaBr₅ | or plasma- |
| | TaI₅ | activated N₂/H₂ |
| | | mixed gas); |
| | | H⁺/H* (plasma- |
| | | activated H₂ |
| | | gas) |

Table 15 illustrates examples of the first and second source gases used to form the first Cu-diffusion barrier film, as well as examples of the first and second source gases used to form the second Cu-diffusion barrier film, when a WN/W(C)N layered film is formed. By using any one of the source gases listed in Table 15, the above-described effect can be achieved. It should be noted that if plasma-activated H₂ gas (H⁺/H*) is used as the second source gas to form the second Cu-diffusion barrier film, a W/W(C)N film is formed, in place of the WN/Ta(C)N film, which film can achieve the same effect.

TABLE 15

| | FIRST SOURCE GAS | SECOND SOURCE GAS |
|---|---|---|
| 1^{st} Cu-DIFFUSION | W(CO)₆ | NH₃ |
| BARRIER FILM | | N₂H₄ |
| | | NH(CH₃)₂ |
| | | N₂H₃CH₃ |
| 2^{nd} Cu-DIFFUSION | WF₆ | NHx* (plasma-activated |
| BARRIER FILM | | NH₃, or plasma- |
| | | activated N₂/H₂ |
| | | mixed gas); |
| | | H⁺/H* (plasma- |
| | | activated H₂ gas) |

Any combination of the first and second source gases illustrated in Example 7 allows a high-quality Cu-diffusion barrier film, without damaging underlying layers located beneath the Cu-diffusion film.

### Example 8

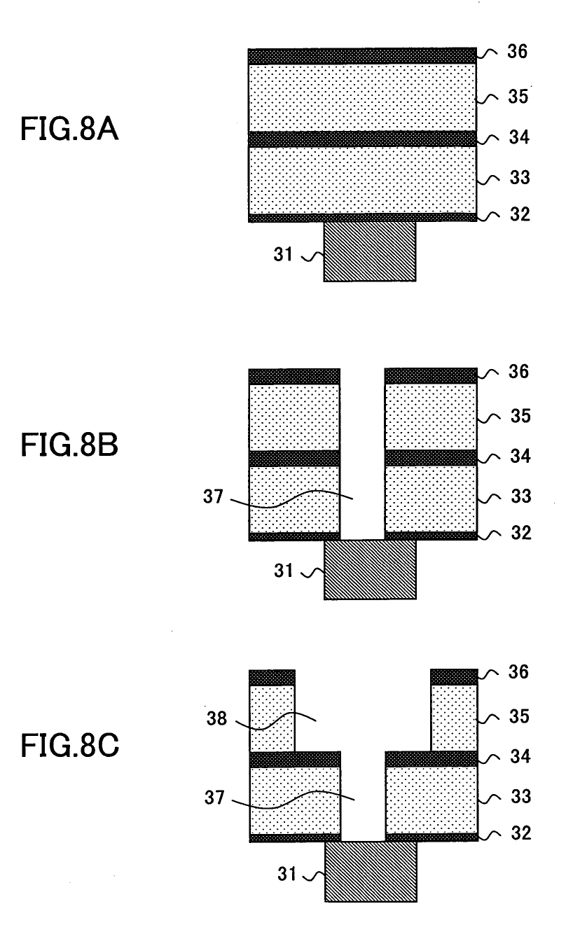

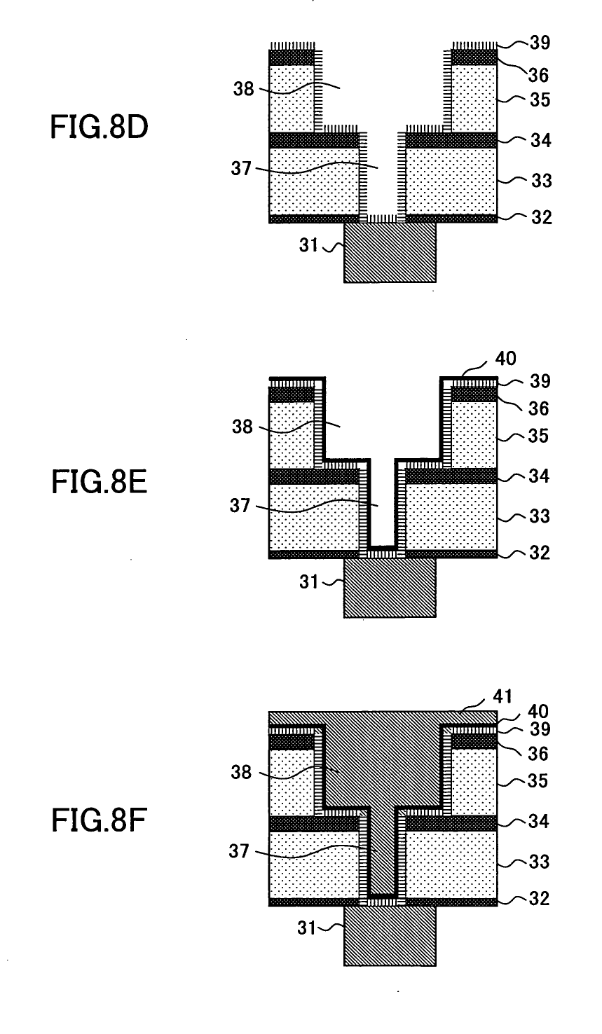

FIG. 8A through FIG. 8F illustrate a fabrication process of a semiconductor device, using the film formation method of Example 5.

FIG. 8A illustrates a copper (Cu) interconnect line 31 formed over a semiconductor substrate (not shown) on which MOS transistors are arranged. The copper (Cu) interconnect line 31 is electrically connected to a lower-level interconnect line (not shown) coupled to the MOS transistors. The copper (Cu) interconnect line 31 is covered with a cap film 32, a first dielectric film 33, a first mask film 34, a second dielectric film 35, and a second mask film 36.

In FIG. 8B, the second mask film 36, the second dielectric film 35, the first mask film 34, the first dielectric film 33, and the cap film 32 are successively etched by plasma etching so as to form a cylindrical hole 37 reaching the copper interconnect line 31. If the first and second dielectric films 33 and 35 are inorganic films, such as silicon oxide or fluorine-added silicon oxide, then fluorocarbon gas, such as CF₄ or C₂F₆ is used as the etching gas. If the first and second dielectric films 33 and 35 are organic films, O₂, H₂, or N₂ is used as the etching gas. For the cap film 32, the first mask film 34, and the second mask film 36, appropriate etching gases are also selected, and dry etching is performed while switching the etching gases.

In FIG. 8C, so-called trench etching is performed to form a groove 38 in the second mask film 36 and the second dielectric film 35. This etching process is also a dry process, as in the via-hole etching shown in FIG. 8B. The etching gas is appropriately selected so as to be suitable for the materials of the second dielectric film 35 and the second mask film 36. The etching gas may be switched as necessary, depending on the combination of the second mask 36 and the second dielectric film 35.

The steps shown in FIG. 8B and FIG. 8C may be switched, that is, trench etching may be performed prior to the via-hole etching.

Then, in FIG. 8D, the first Cu-diffusion barrier film 39 is formed of titanium nitride (TiN), according to S104 through S108 shown in FIG. 5. In this step, film formation is performed layer by layer (on the atomic or molecular layer basis), which is superior in coverage even at the hole 37 or the groove 38. Accordingly, a high-quality TiN film 39 can be formed uniformly over the minute pattern.

Since non-plasma-activated NH₃ is used as the second source gas to form the TiN film 39, as described in Example 1, damaging species, such as ions or radicals, are not contained in the second source gas. This arrangement can prevent the first dielectric film 33 or the second dielectric film 35 from being damaged.

Then, in FIG. 8E, the second Cu-diffusion barrier film 40 is formed of titanium nitride (TiN), applying S109 through S113 shown in FIG. 5. The film formation is performed layer by layer (on the atomic or molecular layer basis), as in forming the first Cu-diffusion barrier film 39, and the TiN film 40 can be formed over the minute pattern, with satisfactory film quality and high coverage of the hole 37 and the groove 38.

In this step, plasma-activated NH₃ is used as the second source gas to promote dissociation of the gas and advance the reaction with TiCl₄ supplied as the first source gas. Consequently, the impurity content, such as chlorine (Cl) content, in the TiN film can be reduced, and a high-quality TiN film with less electric resistance is obtained.

The first dielectric film 33 and the second dielectric film 35 are covered with the first Cu-diffusion barrier film 39 during the formation of the second Cu-diffusion barrier film 40 using plasma-activated gas. Accordingly, the first dielectric film 33 and the second dielectric film 35 are protected from damage by ions or radicals existing in the plasma-activated gas. In other words, by employing the double-layered structure, a high-quality Cu-diffusion film with less impurity content can be realized, while preventing damage to the underlying first dielectric film 33 and second dielectric film 35.

Then, in FIG. 8F, copper (Cu) film 41 is formed by a PVD method, a CVD method, or plating, so as to fill the hole 37 and the groove 38. Then, the entire surface is flattened by chemical mechanical polishing (CMP) to remove the copper film 41, as well as the first Cu-diffusion barrier film 39 and the second Cu-diffusion barrier film 40, until the second mask film 36 is exposed. At this point of time, the top face of the Cu film 41 filling the groove 38 aligns with the top face of the second mask film 36. The second mask film 36 may be removed by this polishing process, as necessary.

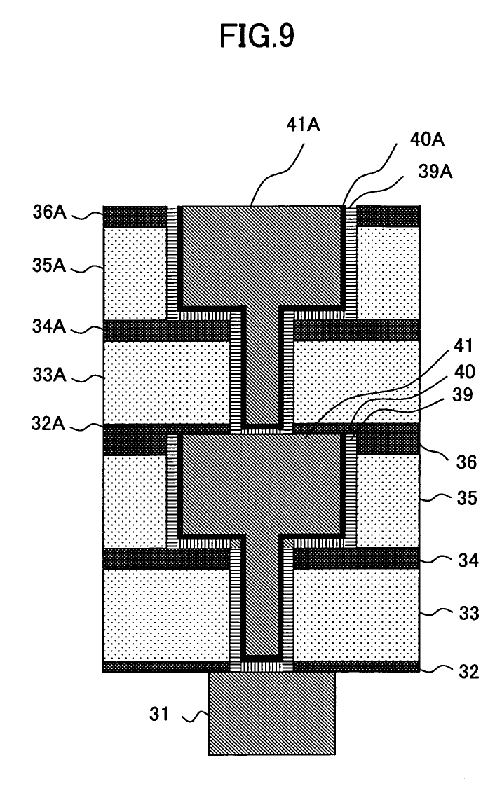

The film formation method can also be applied to fabrication of a semiconductor device with multilevel interconnect lines, as illustrated in FIG. 9. The same components as those already explained above are denoted by the same symbols, and explanation for them is omitted.

The semiconductor device of FIG. 9 is fabricated by further applying the above-described film formation process after the step shown in FIG. 8F.

For example, after the CMP performed in FIG. 8F, another cap film 32A, another first dielectric film 33A, another first mask film 34A, another second dielectric film 35A, and another second mask film 36A are successively formed over the Cu interconnect line 41. Then, the process illustrated in FIG. 8A through FIG. 8F is repeated to form another first Cu-diffusion barrier film 39A, another second Cu-diffusion film 40A, and another copper (Cu) film 41A over the lower-level copper interconnect line 41. Still another level of interconnect line may be formed by repeating the same process by further depositing dielectric films and conductive films over the Cu film 41A.

When a TiN film is formed as the Cu-diffusion barrier film, the first source gas and the second source gas may be altered, as described in Example 5.

In addition, by changing the first source gas and the second source gas, another type of Cu-diffusion barrier film, such as TaN film, Ta/TaN layered film, WN film, W/WN layered film, Ti(C)N film, Ta(C)N film, W(C)N film, or W(C)/W(C)N layered, may be formed.

In either case, a high-quality Cu-diffusion film with less impurity content can be obtained, without damaging the underlying first dielectric film 33 or second dielectric film 35, by employing the double layered structure of the first and second Cu-diffusion films.

Dielectric films (such as the first dielectric film 33 and the second dielectric film 35) may be roughly grouped into inorganic films and organic films.

Examples of inorganic dielectric film include alkyl siloxane polymer and HSQ (hydrogenated silsesquioxane polymer), which are known as inorganic spin-on dielectric (SOD) film formed by spin coat. Low dielectric constant films are formed by chemical vapor deposition (CVD), and an example of inorganic low dielectric constant film formed by CVD includes fluoridated silicon dioxide film.

The above-described inorganic films and silicon dioxide films can be made porous to further decrease the permittivity.

Examples of organic dielectric film include organic polymer films, such as films of PTFE group, polyamide group, fluoridated polyamide, BCB (benzocyclobutene), parylene-N, parylent-F, MSQ (alkyl silsesquioxane polymer), and HOSP (hydrogenated alkyl silsesquioxane polymer). Examples of organic low dielectric constant film formed by CVD include fluoridated carbon films, diamond-like carbon (DLC) films, SiCO films, and SiCO(H) films.

These organic films can also be formed as porous films to further decrease the permittivity.

### Example 9

In Example 9, the film formation method shown in Example 6 is applied to another fabrication process of a semiconductor device. In this case, the steps of forming the first Cu-diffusion barrier film 39 and the second Cu-diffusion barrier film 40 illustrated in Example 8 in conjunction with FIG. 8D and FIG. 8E, respectively, are modified.

To be more precise, steps S204 to S208 illustrated in FIG. 6 are applied to form the first Cu-diffusion barrier film shown in FIG. 8D. As the first source gas, TEMAT, which is a metal-organic gas, is used in place of the halogen compound gas, in order to prevent corrosion of the underlying copper (Cu) film 31 by halogen.

Then, steps S209 through S213 illustrated in FIG. 6 are applied to form the second Cu-diffusion barrier film shown in FIG. 8E. As the first source gas, TiCl₄, which is a halogen compound gas, is used to prevent organic compounds including carbon (C) and CHx from being taken into the film and to reduce the electric resistance of the resultant TiN film.

During the formation of the second Cu-diffusion barrier film 40, the underlying copper film 31 is covered with the first Cu-diffusion barrier film 39, and therefore is not damaged by the halogen contained in the first source gas. The same applies to other metals, such as tungsten (W) or aluminum (Al), used in the underlying film.

As the first Cu-diffusion barrier film, a Ti(C)N film of satisfactory quality, with less impurity content, can be formed without damaging the underlying copper film 31.

By appropriately selecting the first source gas and the second source gas, various types of layered film, including TaN/Ta(C)N film, Ta/Ta(C)N film, WN/W(C)N film, and W/W(C)N film, can be formed. By forming a double-layered Cu-diffusion barrier film with the first and second Cu-diffusion barrier films, the impurity content is reduced as a whole, while preventing damage to the underlying metal layer.

### Example 10

In Example 10, the film formation method shown in Example 7 is applied to another fabrication process of a semiconductor device. In this case, the steps of forming the first Cu-diffusion barrier film 39 and the second Cu-diffusion barrier film 40 illustrated in Example 8 in conjunction with FIG. 8D and FIG. 8E, respectively, are modified.

To be more precise, steps S304 to S308 illustrated in FIG. 7 are applied to form the first Cu-diffusion barrier film shown in FIG. 8D. As the second source gas, non-plasma-activated NH₃ gas is used to exclude damaging species, such as ions or radicals, so as not to damage the underlying first dielectric film 33 and second dielectric film 35.

In addition, a metal-organic gas TEMAT is used as the first source gas, in place of the halogen compound gas, to prevent the underlying copper film 31 from corroding due to halogen. Consequently, all the underlying films, including the first and second dielectric films 33 and 35 and the metal film (Cu film) 31, are protected from the damage.

Then, steps S309 through S313 illustrated in FIG. 7 are applied to form the second Cu-diffusion barrier film shown in FIG. 8E. Plasma-activated NH₃ gas is used as the second source gas to promote dissociation and advance reaction with the first source gas. Consequently, the impurity content in the film can be reduced, and the second Cu-diffusion barrier film with satisfactory quality and less electric resistance can be obtained.

Since the underlying first dielectric film 33 and second dielectric film 35 are covered with the first Cu-diffusion barrier film 39 during the formation of the second Cu-diffusion barrier film 40, they are protected from damage by ions or radicals existing in the plasma-activated gas.

As the first source gas, TiCl₄, which is a halogen compound gas, is used to prevent organic compounds including carbon (C) and CHx from being taken into the film and to reduce the electric resistance of the resultant TiN film.

Since the underlying copper film 31 is covered with the first Cu-diffusion barrier film 39 during the formation of the second Cu-diffusion barrier film 40, the copper film 31 is protected from damage by halogen contained in the first source gas. The same applies to other metals, such as tungsten (W) or aluminum (Al), used in the underlying film.

By forming double-layered Cu-diffusion film with the first and second Cu-diffusion films 39 and 40, the impurity content is reduced as a whole, while preventing damage to all the underlying films, including the first and second dielectric films 33 and 35 and the copper film 31.

As described in Example 7, the first source gas and the second source gas may be selected appropriately to form the TiN/Ti(C)N diffusion barrier film. In this case, various types of layered film, including TaN/Ta(C)N film, Ta/Ta(C)N film, WN/W(C)N film, and W/W(C)N film, can be formed. In any one, the impurity content in the barrier film is reduced as a whole, while preventing damage to the dielectric film and the metal film.

Regardless of the types and materials of the underlying dielectric films 33 and 35, the film formation method is effectively applied, as described in Example 8.

### Example 11

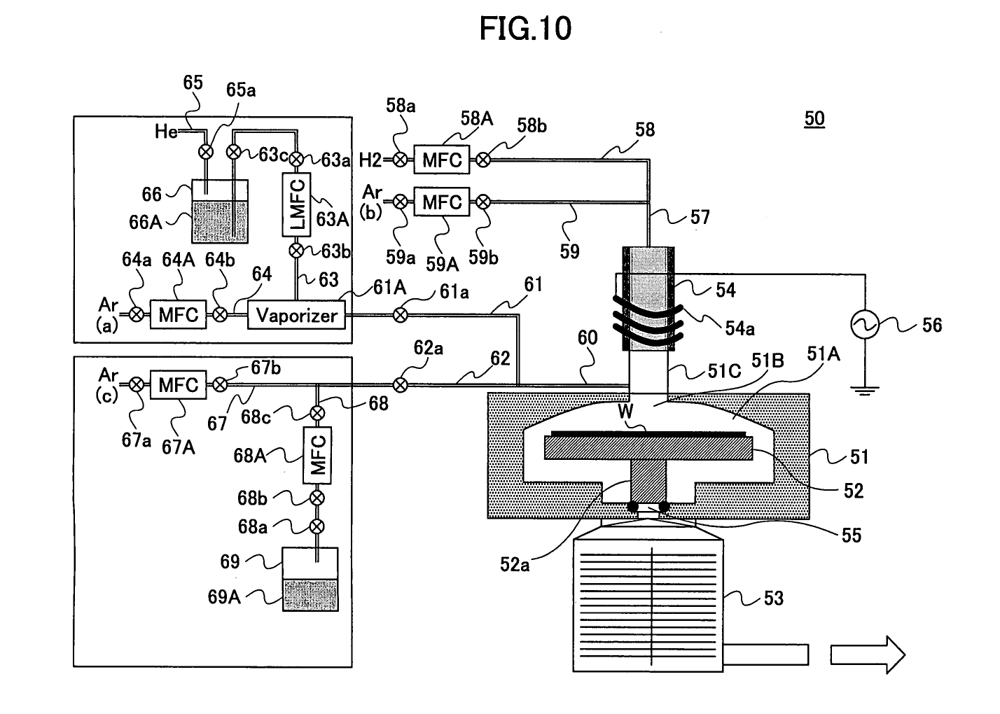

The first and second Cu-diffusion barrier films can be formed using a film deposition apparatus 50 illustrated in FIG. 10

In FIG. 10, the film deposition apparatus 50 includes a processing chamber 51 made of, for example, aluminum, surface-treated (alumite treated) aluminum, or stainless steel. A wafer stage 52 made of aluminum nitride (AlN) and for holding a substrate or a wafer is supported on a base 52a in the processing chamber 51. A semiconductor wafer W is placed on the center of the wafer stage 52. A heater (not shown) is provided inside the wafer stage 52 to heat the wafer W to a desired temperature.

The inner space 51A of the processing chamber 51 is connected to an evacuation port 55, and evacuated by evacuation means 53, such as a turbo molecular pump. Thus, the inner space 51A of the processing chamber 51 is maintained under reduced pressure. The wafer W to be processed is transported into or out of the processing chamber 51 through a gate valve (not shown).

The processing chamber 51 is furnished with an opening 51B, which opening is connected to a gas supply tube 51C through which the first source gas and the second source gas are introduced into the chamber 51.

A gas supply line 60 extends from the gas supply tube 51C to supply the first source gas. The gas supply line 60 is connected to a halogen compound gas supply line 62 via the valve 62a, and to a metal-organic gas supply line 61 via the valve 61a.

The metal-organic gas supply line 61 is connected to a vaporizer 61A, which vaporizer is further connected to a gas line 63 furnished with valves 63a, 63b, and 63c and a liquid mass flow controller 63A. The gas line 63 is coupled with a tank 66 containing a source material 66A of the metal-organic first source gas. An example of the source material 66A is Taimata (registered trademark), consisting of Ta(NC(CH₃)₂C₂H₅) (N(CH₃)₂)₃.

The tank 66 is also connected to a gas line 65 furnished with a valve 65a, through which an inert gas, such as helium (He) gas, is supplied to the tank 55. The material 66A contained in the tank 66 is pressurized by the inert gas, and heated to 50° C. by a heater (not shown).

The pressurized and heated material 66A is supplied to the vaporizer 61A under the control of the liquid mass flow controller 63A. The vaporizer 61A is connected to the gas line 64 furnished with the valve 64a and 64b, as well as the mass flow controller 64A. The evaporated material 66A is supplied from the vaporizer 61A to the processing chamber 51, together with a carrier gas (such as argon (Ar) gas) supplied from the gas line 64, through the gas lines 61, the gas line 60, and the gas supply tube 51C.

The material 66A may be supplied after it is dissolved in an organic solvent, such as octane or hexane. In this case, the tank 66 may not be heated. By stirring the organic solvent using an agitation stick, the material 66A is dissolved uniformly in the organic solvent.

The gas line 62 is connected to a gas line 68 furnished with valves 68a, 68b, and 68c and the mass flow controller 68A. The gas line 68 is connected to a tank 69 that contains a halogen material 69A of the first source gas, such as TaCl₅.

The tank 69 is heated to, for example, 150° C., to evaporate the material 69A consisting of TaCl₅. The evaporated material 69A is supplied under the control of the mass flow controller 68A to the inner space 51 of the processing chamber, via the gas line 62, the gas line 60, and the gas supply tube 51C. Simultaneously, an inert gas (e.g., Ar gas) may be supplied to the processing chamber 51, together with this evaporated source gas, through the gas line 67 furnished with valves 67a and 67b and the mass flow controller 67A.

The gas supply tube 51C is also connected to the gas line 57 via a plasma source 54 (which is described below). The gas line 57 is then branched into a gas line 58 and a gas line 59. The gas line 58 is furnished with valves 58a and 58b and a mass flow controller 58A, and is used to supply the second source gas consisting of, for example, H₂ to the plasma source 54. The gas line 59 is furnished with valves 59a and 59b and a mass flow controller 59A, and is used to supply a carrier gas (such as Ar gas) to the plasma source 54.

The plasma source 54 is made of a dielectric material, such as Al₂O₃, quartz, SiN or BN, and it has a substantially cylindrical shape. A coil 54a is wound around the cylindrical plasma source 54, and connected to a high-frequency power supply 56. High frequency power is applied to the coil 54a by the power supply 56 to excite the second source gas supplied into the plasma source 54 into plasma, as necessary. Reactive species, such as ions and radicals, are produced from the plasma-activated gas, and supplied to the processing chamber 51 via the gas supply tube 51C.

The plasma is generated by an inductively coupled plasma (ICP) generator at a high frequency of 13.56 MHz. Plasma excitation may be performed by a parallel plate plasma system or an ECR plasma system. The plasma may be generated at a lower frequency, such as 400 kHz or 800 kHz, or alternatively, radio waves or microwaves (2.45 GHz) may be used. Any suitable method or frequency can be employed as long as the gas is dissociated into excited plasma.

The operations of the film deposition apparatus 50, including the opening and closing of the valves and plasma excitation of the plasma source 54, are comprehensively controlled by a controller (not shown).

Next, explanation is made of formation of the Cu-diffusion barrier film using the film deposition apparatus 50.

### Example 12

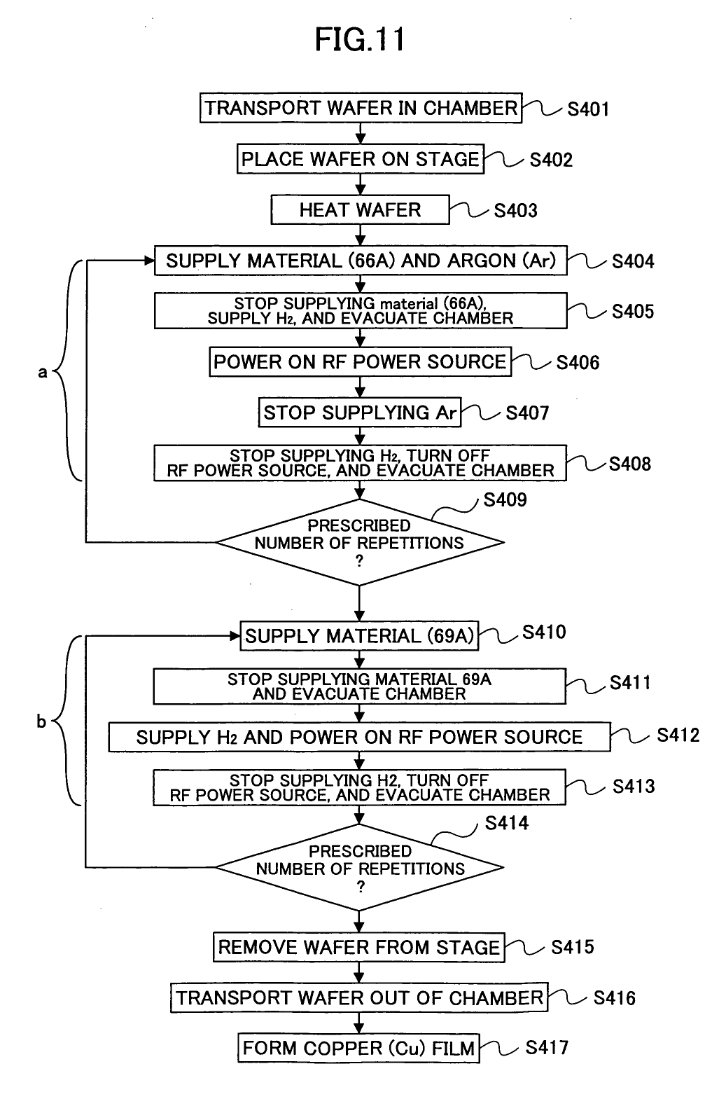

FIG. 11 is a flowchart showing the process flow of the film deposition apparatus 50 when forming the Cu-diffusion barrier film. In this example 1, a Ta/Ta(C)N layered film is formed as the Cu-diffusion barrier film.

In step S401, the wafer W to be processed is transported into the film deposition apparatus 50.

Then, in step S402, the wafer W is placed onto the wafer stage 52.

Then, in step S403, the wafer W is heated by the heater set inside the wafer stage 52, and is maintained at about 270° C. in this step and the subsequent steps.

Then, in step S404, the valves 65a, 63a, 63b, 63c, and 61a are opened to apply pressure to the tank 66 and supply liquid material 66A consisting of Ta(NC(CH₃)₂C₂H₅) (N(CH₃)₂)₃ through the gas line 63, under the control of the mass flow controller 63A, so as to supply the liquid material 66A to the vaporizer 61A at 20 mg/min.

The evaporated material 66A is supplied to the processing chamber 51, together with argon (Ar) of 200 sccm supplied to the vaporizer 61A through the gas line 64.

At the same time, the valves 59a and 59b are also opened to supply argon (Ar) gas at 100 sccm under the control of the mass flow controller 59A to the processing chamber 51 through the gas line 57. This Argon gas flow prevents the evaporated material 66A from flowing back to the plasma source 54 through the gas supply tube 51C.

The material 66A is supplied and adsorbed onto the wafer W.

Then, in step S405, the valves 65a, 63a, 63b, 63c, and 61a are closed to stop supplying the material 66A to the processing chamber 51. The residual material 66A remaining in the processing chamber 51, without being adsorbed onto the wafer W, is purged from the evacuation port 55.

In this step, the valves 58a and 58b are opened to supply H₂ gas to the processing chamber 51 at 200 sccm under the control of the mass flow controller 58A, through gas line 57. The mass flow controller 59A is also controlled to adjust the argon (Ar) gas flow through the gas line 57 to 200 sccm.

Then, in step S406, high-frequency power of 800 W is applied to the coil 54a to perform plasma excitation in the plasma source 54. Since the H₂ gas supply has already started in the previous step S405, the mass flow of the H₂ gas is stable at the beginning of step S406, and plasma excitation is performed promptly upon application of the high-frequency power.

Then, in step S407, the argon (Ar) gas supply through the gas line 57 is stopped, such that only H₂ gas is supplied to the plasma source 54. In the plasma source 54, the hydrogen gas is dissociated into H+/H* (hydrogen ions and hydrogen radicals), and the plasma-activated hydrogen is supplied into the processing chamber 51. The ions and radicals H+/H* react with the material 66A adsorbed onto the substrate to form a Ta(C)N film. By stopping the argon (Ar) gas supply, the hydrogen ions and radicals (H+/H*) reach the peripheral portion of the substrate, and the reaction with the material 66A is promoted.

Then, in step S408, the valves 58a and 58b are closed to stop supplying the hydrogen gas to the plasma source 54, that is, to stop supplying the hydrogen ions and radicals to the processing chamber 51. The residual reactive species H+/H*, H2, or by-product materials of the reaction are purged out of the chamber 51 through the evacuation port 55.

The processing times in steps S404, S405, S406, S407, and S408 are 3 seconds, 3 seconds, 10 seconds, 10 seconds, and 1 second, respectively.

Then, in step S409, the process returns to step S404 to repeat steps S404 through S408 until a desired thickness of Ta(C)N film (the first Cu-diffusion barrier film) is obtained. After the necessary number of repetitions, the process proceeds to step S410.

Then, in step S410, the valves 68a, 68b, 68c, and 62a are opened to supply the material 69A, which is evaporated TaCl₅, to the processing chamber 51 at 3 sccm under the control of mass flow controller 68A.

Simultaneously, the valves 59a and 59b are opened to supply argon (Ar) gas at 200 sccm under the control of the mass flow controller 59A, to the processing chamber 51 through the gas supply line 57. This argon (Ar) gas flow prevents the evaporated material 69A from flowing back to the plasma source 54 through the gas supply tube 51C.

The evaporated material 69A is supplied and adsorbed onto the substrate.

Then, in step S411, the valves 68a, 68b, 68c, and 62a are closed to stop supplying the material 69A to the processing chamber 51. The residual material 69A remaining in the processing chamber 51, without being adsorbed onto the wafer W, is purged from the evacuation port 55.

Then, in step S412, the argon (Ar) gas supply through the gas line 57 is stopped, and the valves 58a and 58b are opened to supply H₂ gas to the plasma source 54 at 750 sccm under the control of the mass flow controller 58A, through gas line 58. High-frequency power of 1000 W is applied to the coil 54a to perform plasma excitation in the plasma source 54.

In the plasma source 54, the hydrogen gas is dissociated into H+/H* (hydrogen ions and hydrogen radicals), and the plasma-activated hydrogen is supplied into the processing chamber 51. The ions and radicals H+/H* react with the material 69A adsorbed onto the substrate to form a tantalum (Ta) film.

Then, in step S413, the application of the high-frequency power is stopped, and the valves 58a and 58b are closed to stop supplying the hydrogen gas to the plasma source 54, that is, to stop supplying the hydrogen ions and radicals to the processing chamber 51. The residual reactive species H+/H*, H2, or by-product materials of the reaction are purged out of the chamber 51 through the evacuation port 55.

Then, in step S414, the process returns to step S410 to repeat steps S410 through S413 until a desired thickness of Ta film (the second Cu-diffusion barrier film) is obtained. After the necessary number of repetitions, the process proceeds to step S415.

Then, in step S416, the processed wafer W is transported out of the processing chamber 51.

Then, in step S417, the wafer is transported into a copper (Cu) film deposition apparatus, such as a plating apparatus, a PVD apparatus, or a CVD apparatus, to form a copper (Cu) film over the second Cu-diffusion barrier film.

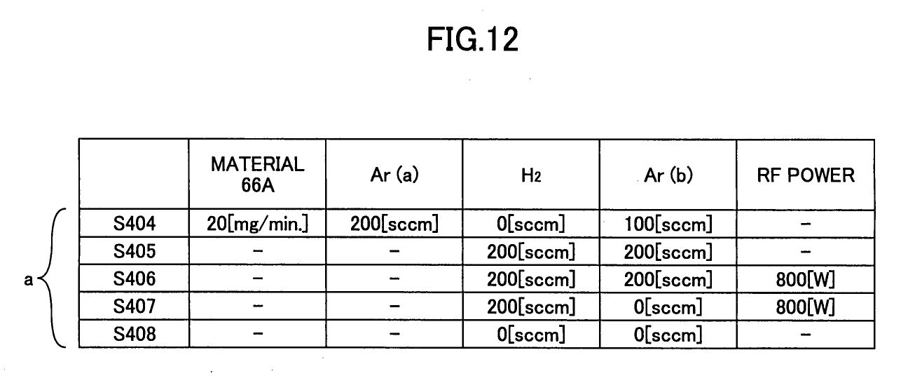

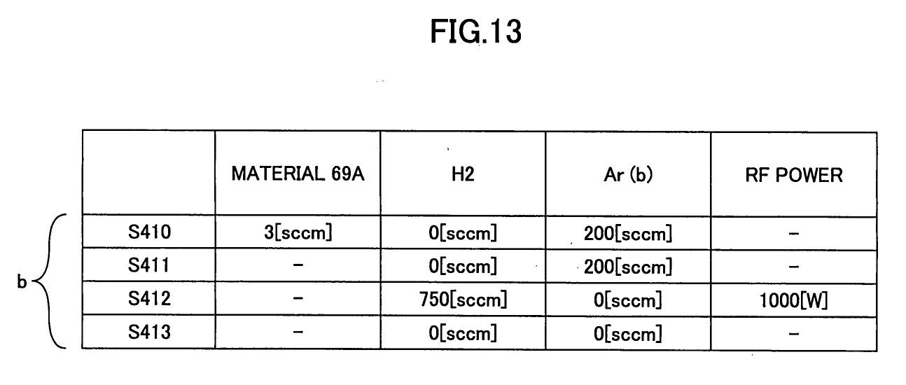

FIG. 12 and FIG. 13 illustrate film deposition conditions for the first film deposition process “a” (steps S404 through S409) and the second film deposition process “b” (steps S410 through S414), respectively, shown in FIG. 11. In these figures, Ar(a) denotes the carrier gas supplied through the gas line 64, and Ar(b) denotes the argon (Ar) gas supplied through the gas line 59.

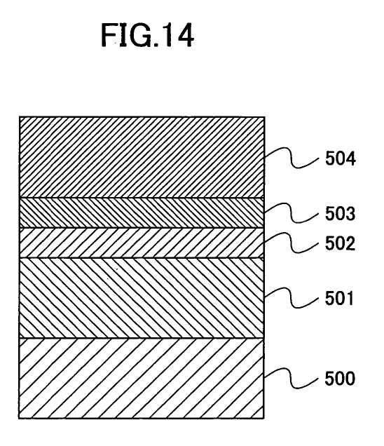

FIG. 14 illustrates an example of the Cu-diffusion barrier film formed on a wafer. The first Cu-diffusion barrier film 502 consisting of Ta(C)N with a thickness of 5 nm is formed over the silicon oxide (SiO₂) film 501 with a thickness of 100 nm on the wafer 500, by repeating the process “a” 30 times under the conditions illustrated in FIG. 12.

The second Cu-diffusion barrier film 503 consisting of tantalum (Ta) with a thickness of 3 nm is formed over the first Cu-diffusion barrier film 502, by repeating the process “b” 300 times under the conditions illustrated in FIG. 13. Over the second Cu-diffusion barrier film 503 is a copper (Cu) film 504 with thickness of 100 nm formed in step S417 shown in FIG. 11.

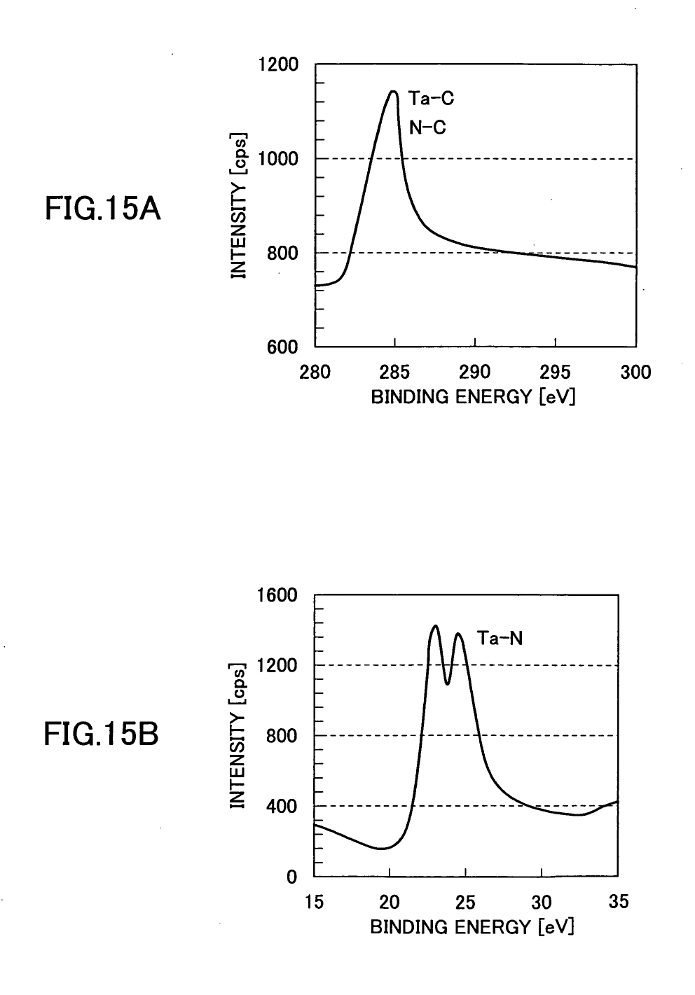

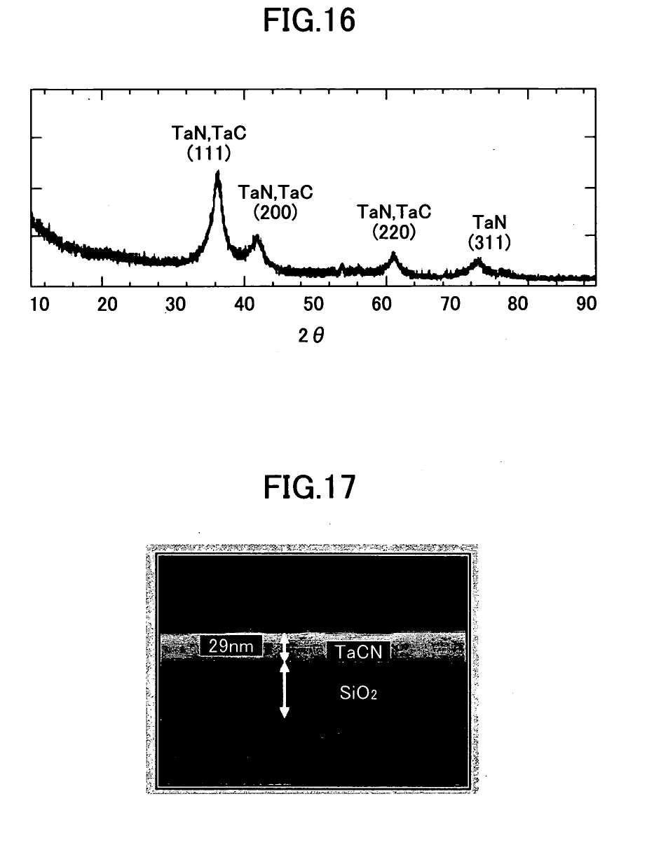

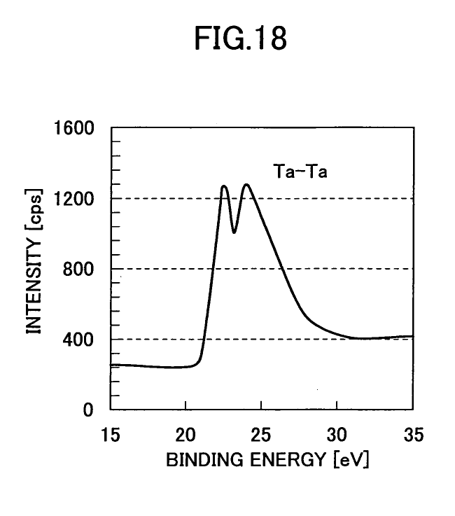

FIG. 15A, FIG. 15B, and FIG. 16 through FIG. 20 illustrate analysis results of the Ta(C)N film, which is the first Cu-diffusion barrier film, and the Ta film, which is the second Cu-diffusion barrier film. To be more precise, FIG. 15A, FIG. 15B, FIG. 16 and FIG. 17 show the analysis result of the Ta(C)N first Cu-diffusion barrier film formed at 220° C. by repeating the process “a” shown in FIG. 11 two hundred (200) times, and FIG. 18 through FIG. 20 show the analysis result of the tantalum second Cu-diffusion barrier film formed at 270° C. by repeating the process “b” shown in FIG. 11 three hundred (300) times.

FIG. 15A and FIG. 15B are X-ray photoelectron spectroscopy (XPS) analysis results of the Ta(C)N film. FIG. 15A shows the C1s spectrum, and FIG. 15B shows the Ta4f spectrum. From these graphs, it is understood that Ta—C bond, N—C bond, and Ta—N bond exist in the Ta(C)N film.

FIG. 16 shows X-ray diffraction (XRD) analysis result of the Ta(C)N film. The (111) plane, the (200) plane, the (220) plane, and the (311 plane) of TaN and TaC are observed in the Ta(C)N film.

FIG. 17 is a cross-sectional SEM photograph of the Ta(C)N film. It is seen from the SEM photograph that a Ta(C)N film with thickness of 29 nm is formed over the SiO₂ film on the substrate, according to the method illustrated in FIG. 11. The specific resistance value of the Ta(C)N film shown in FIG. 17 is 740 μΩ-cm.

FIG. 18 shows the X-ray photoelectron spectroscopy (XPS) analysis result of the tantalum (Ta) film, which is the second Cu-diffusion barrier film. It is clearly seen from FIG. 18 that Ta—Ta bond exists in the tantalum film.

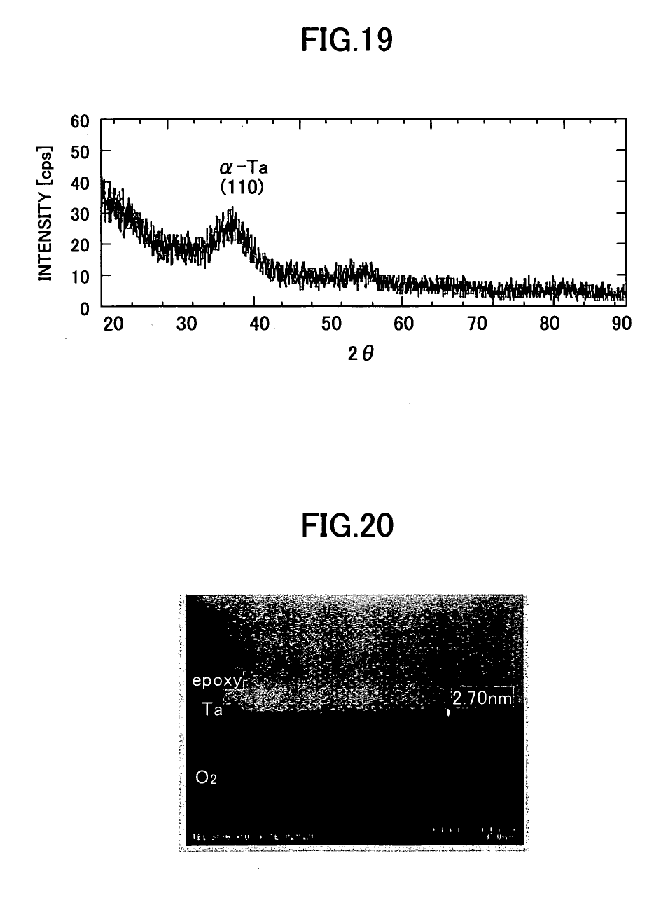

FIG. 19 is the XRD analysis result of the tantalum (Ta) film. The (110) plane of the α-Ta is observed in the tantalum film.

FIG. 20 is a cross-sectional TEM (transmission electron microscope) photograph of the tantalum (Ta) film formed over the SiO₂ film. It is seen from the photograph that the tantalum film with thickness of 2.7 nm is formed over the substrate.

### Example 13

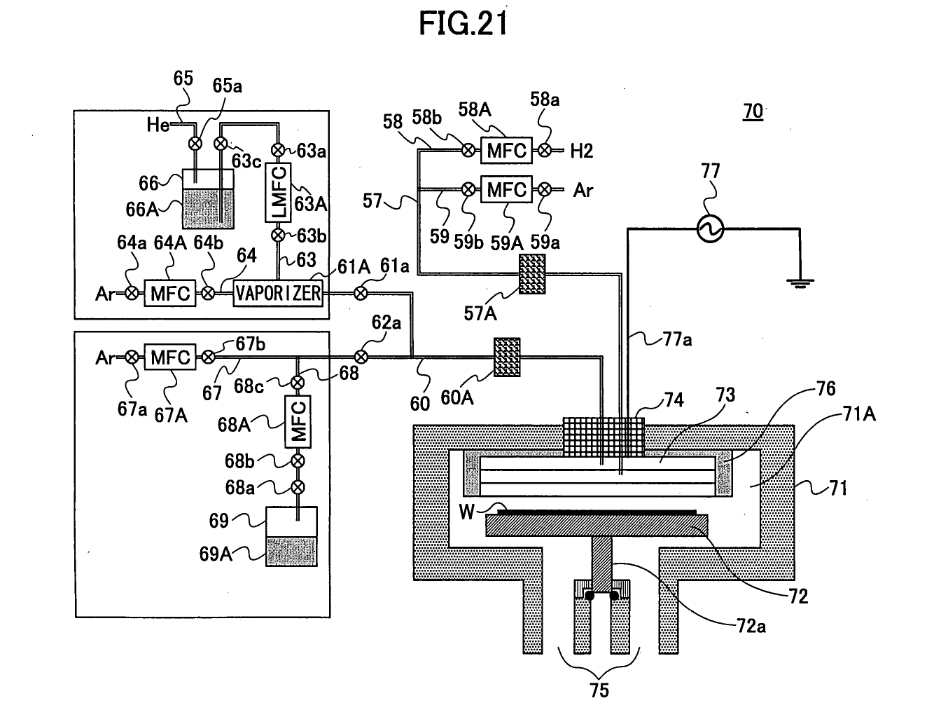

The double-layered Cu-diffusion barrier film consisting of the first and second Cu-diffusion barrier films may be formed using a film deposition apparatus 70 shown in FIG. 21, in a manner similar to the examples using the film deposition apparatuses 10 and 50. The same components as those illustrated in the previous examples are denoted by the same symbols, and explanation for them is omitted.

In FIG. 21, the film deposition apparatus 70 includes a processing chamber 71 made of, for example, aluminum, surface-treated (alumite treated) aluminum, or stainless steel. A wafer stage 72 made of, for example, Hastelloy and for holding a substrate or a wafer is supported on a base 72a in the processing chamber 71. A semiconductor wafer W is placed on the center of the wafer stage 72. A heater (not shown) is provided inside the wafer stage 72 to heat the wafer W to a desired temperature.

The inner space 71A of the processing chamber 71 is connected to an evacuation port 75, and evacuated by evacuation means (not shown) to maintain the inner space 71A of the processing chamber 71 under reduced pressure. The wafer W to be processed is transported into or out of the processing chamber 71 through a gate valve (not shown).

A substantially cylindrical shower head 73 is provided in the processing chamber 71 so as to face the wafer stage 72. An insulator 76 made, for example, quartz or ceramics (such as SiN or AlN), is provided so as to cover the shower head 73, leaving the bottom facing the wafer stage 72 uncovered.

An opening is provided to the processing chamber 71, through which opening an insulator 74 made of a dielectric material is inserted. A lead 77a connected to a high-frequency power supply 77 penetrates through the insulator 74 such that the other end of the lead 77a is connected to the shower head 73. High frequency power is applied to the shower head 73 via the lead 77a.

An insulator 60A made of a dielectric material, such as quartz or ceramics (SiN, AlN, or Al₂O₃), is inserted in the gas line 60. Accordingly, the gas line 60 is connected to the shower head 73 via the insulator 60A. The insulator 60A electrically insulates the gas line 60, through which materials 66A and 69A are supplied, from the shower head 73.

Similarly, an insulator 57A made of a dielectric material, such as quartz or ceramics (SiN, AlN, or Al₂O₃), is inserted in the gas line 57. Accordingly, the gas line 57 is connected to the shower head 73 via the insulator 57A. The insulator 57A electrically insulates the gas line 57, through which H₂ gas and Ar gas are supplied, from the shower head 73. A gas containing a hydrogen compound may be supplied, in addition to the hydrogen (H₂) gas, through the gas line 57.

When supplying H₂ gas or Ar gas to the processing chamber 71, a high power is applied to the shower head 73 to perform plasma excitation by the high-frequency power supply 77, as necessary. In this structure, plasma excitation is performed in the inner space 71A of the processing chamber 71 to dissociate the H₂ gas.

Using the film deposition apparatus 70, the first Cu-diffusion barrier film made of Ta(C)N and the second Cu-diffusion barrier film made of tantalum (Ta) can be formed, in a manner similar to Example 12. The film deposition apparatus 70 is capable of carrying out the film formation process shown in Examples 1 through 3.

With the present invention, a Cu-diffusion barrier film with satisfactory quality can be formed without damaging underlying films.

The formed Cu-diffusion barrier film contains a lesser amount of impurities, has good crystal orientation, and satisfactory coverage over a minute pattern.

Although the invention has been described using specific examples, the invention is not limited to these examples, and there are many modifications and substitutions within the scope of the invention defined by the appended claims.

What is claimed is:

1. A film fabrication method for forming a film over a substrate in a processing chamber, comprising:
a first film formation process of repeating
a first step of supplying a first source gas containing a metal into the chamber and then removing the first source gas from the chamber; and
a second step of supplying a second source gas containing hydrogen or a hydrogen compound into the chamber and then removing the second source gas from the chamber; and
a second film formation process of repeating
a third step of supplying the first source gas into the chamber and removing the first gas from the chamber; and
a fourth step of supplying a plasma-activated third source gas containing hydrogen or a hydrogen compound into the chamber and removing the third source gas from the chamber.

2. The film fabrication method of claim 1, wherein the first film formation process includes film growth over an underlying film, including a dielectric film, formed on the substrate.

3. The film fabrication method of claim 2, wherein the film growth is performed over the dielectric film including an inorganic SOD film.

4. The film fabrication method of claim 2, wherein the film growth is performed over the dielectric film including an organic polymer.

5. The film fabrication method of claim 2, wherein the film growth is performed over the dielectric film including a porous film.

6. The film fabrication method of claim 1, wherein the first film formation process is performed to form a first copper-diffusion barrier film, and the second film formation process is performed to form a second copper-diffusion barrier film.

7. The film fabrication method of claim 2, further comprising the step of:
etching the dielectric film prior to the first film formation process.

8. The film fabrication method of claim 7, wherein the etching step includes via-hole etching for forming a hole in the dielectric film.

9. The film fabrication method of claim 7, wherein the etching step includes trench etching for forming a groove in the dielectric film.

10. The film fabrication method of claim 1, further comprising the step of:
forming a copper film after the second film formation process.

11. A semiconductor device fabrication method comprising:
a first gas supply step of supplying a first source gas containing a metal onto a semiconductor substrate held in a processing chamber and then removing the first source gas from the chamber;
a second gas supply step of supplying a second source gas containing hydrogen or a hydrogen compound onto the semiconductor substrate and then removing the second source gas from the chamber;
a first repetition step of repeating the first and second gas supply steps to form a first film with a predetermined thickness over the semiconductor substrate;
a third gas supply step of supplying the first source gas onto the semiconductor substrate and then removing the first gas from the chamber;
a fourth gas supply step of supplying a plasma-activated third source gas containing hydrogen or a hydrogen compound onto the semiconductor substrate and then removing the third source gas from the chamber; and
a second repetition step of repeating the third and fourth gas supply steps to form a second film with a predetermined thickness over the first film.

12. A machine readable computer program product installed in a film deposition apparatus to cause the film deposition apparatus to execute:
a first film formation process of repeating a predetermined number of times:
a first step of supplying a first source gas containing a metal into a chamber in which a substrate to be processed is placed and then removing the first source gas from the chamber; and
a second step of supplying a second source gas containing hydrogen or a hydrogen compound into the chamber and then removing the second source gas from the chamber; and
a second film formation process of repeating a predetermined number of times:
a third step of supplying the first source gas into the chamber and removing the first gas from the chamber; and
a fourth step of supplying a plasma-activated third source gas containing hydrogen or a hydrogen compound into the chamber and removing the third source gas from the chamber.

13. A recording medium storing a program for causing a film deposition apparatus to execute:
a first film formation process of repeating a predetermined number of times
a first step of supplying a first source gas containing a metal into a chamber in which a substrate to be processed is placed and then removing the first source gas from the chamber; and
a second step of supplying a second source gas containing hydrogen or a hydrogen compound into the chamber and then removing the second source gas from the chamber; and
a second film formation process of repeating a predetermined number of times
a third step of supplying the first source gas into the chamber and removing the first gas from the chamber; and
a fourth step of supplying a plasma-activated third source gas containing hydrogen or a hydrogen compound into the chamber and removing the third source gas from the chamber.

14. A film fabrication method for forming a film over a substrate in a processing chamber, comprising:
a first film formation process of repeating
a first step of supplying a first source gas containing a metal-organic compound and without containing a halogen element into the chamber and then removing the first source gas from the chamber; and
a second step of supplying a second source gas containing hydrogen or a hydrogen compound into the chamber and then removing the second source gas from the chamber; and
a second film formation process of repeating
a third step of supplying a third source gas containing a metal halide compound into the chamber and then removing the third gas from the chamber; and
a fourth step of supplying a plasma-activated fourth source gas containing hydrogen or a hydrogen compound into the chamber and then removing the fourth source gas from the chamber.

15. The film fabrication method of claim 14, wherein the second step and the fourth step include plasma-activation of the second source gas and the fourth source gas.

16. The film fabrication method of claim 14, wherein the metal-organic compound includes a metal-amido compound and a metal-carbonyl compound.

17. The film fabrication method of claim 14, wherein the first step includes film growth over an underlying film including a metal film formed on the substrate.

18. The film fabrication method of claim 17, wherein the underlying metal film is made of copper (Cu), tungsten (W), or aluminum (Al).

19. The film fabrication method of claim 14, wherein the first film formation process is performed to form a first copper-diffusion barrier film, and the second film formation process is performed to form a second copper-diffusion barrier film.

20. The film fabrication method of claim 17, wherein the underlying film includes a dielectric film, the method further comprising the step of:
etching the dielectric film prior to the first film formation process.

21. The film fabrication method of claim 20, wherein the etching step includes via-hole etching for forming a hole in the dielectric film.

22. The film fabrication method of claim 20, wherein the etching step includes trench etching for forming a groove in the dielectric film.

23. The film fabrication method of claim 14, further comprising the step of:
forming a copper film after the second film formation process.

24. A semiconductor device fabrication method comprising:
a first gas supply step of supplying a first source gas containing a metal-organic compound and without containing a halogen element onto a semiconductor substrate held in a chamber and then removing the first source gas from the chamber; and
a second gas supply step of supplying a second source gas containing hydrogen or a hydrogen compound onto the semiconductor substrate and then removing the second source gas from the chamber;
a first repetition step of repeating the first and second gas supply steps to form a first film of a predetermined thickness over the semiconductor substrate;
a third gas supply step of supplying a third source gas containing a metal halide onto the semiconductor substrate and then removing the third gas from the chamber;
a fourth gas supply step of supplying a fourth source gas containing hydrogen or a hydrogen compound onto the semiconductor substrate and then removing the fourth source gas from the chamber; and
a second repetition step of repeating the third and fourth gas supply steps to form a second film of the predetermined thickness over the first film.

25. A machine readable computer product installed in a film deposition apparatus to cause the film deposition apparatus to execute:
a first film formation process of repeating a predetermined number of times
a first step of supplying an first source gas containing a metal-organic compound and without containing a halogen element into a chamber in which a substrate to be processed is placed and then removing the first source gas from the chamber; and
a second step of supplying a second source gas containing hydrogen or a hydrogen compound into the chamber and then removing the second source gas from the chamber; and
a second film formation process of repeating a predetermined number of times
a third step of supplying a third source gas containing a metal halide into the chamber and removing the third gas from the chamber; and
a fourth step of supplying a fourth source gas containing hydrogen or a hydrogen compound into the chamber and removing the fourth source gas from the chamber.

26. A recording medium storing a program for causing a film deposition apparatus to execute:
a first film formation process of repeating a predetermined number of times
a first step of supplying an first source gas containing a metal-organic compound and without containing a halogen element into a chamber in which a substrate to be processed is placed and then removing the first source gas from the chamber; and
a second step of supplying a second source gas containing hydrogen or a hydrogen compound into the chamber and then removing the second source gas from the chamber; and
a second film formation process of repeating a predetermined number of times
a third step of supplying a third source gas containing a metal halide into the chamber and removing the third gas from the chamber; and
a fourth step of supplying a fourth source gas containing hydrogen or a hydrogen compound into the chamber and removing the fourth source gas from the chamber.

27. A film fabrication method for forming a film over a substrate in a processing chamber, comprising:
a first film formation process of repeating
a first step of supplying a first source gas containing a metal-organic compound and without containing a halogen element into the chamber and then removing the first source gas from the chamber; and
a second step of supplying a second source gas containing hydrogen or a hydrogen compound into the chamber and then removing the second source gas from the chamber; and
a second film formation process of repeating
a third step of supplying a third source gas containing a metal halide compound into the chamber and then removing the third gas from the chamber; and
a fourth step of supplying a plasma-activated fourth source gas containing hydrogen or a hydrogen compound into the chamber and then removing the fourth source gas from the chamber.

28. The film fabrication method of claim 27, wherein the metal-organic compound includes a metal-amido compound or a metal-carbonyl compound.

29. The film fabrication method of claim 27, wherein the first film formation process includes film growth over an underlying film, including a dielectric film and a metal film, formed on the substrate.

30. The film fabrication method of claim 29, wherein the underlying dielectric film include an inorganic SOD film.

31. The film fabrication method of claim 29, wherein the underlying dielectric film includes an organic polymer.

32. The film fabrication method of claim 29, wherein the underlying dielectric film includes a porous film.

33. The film fabrication method of claim 29, wherein the underlying metal film is made of copper (Cu), tungsten (W), or aluminum (Al).

34. The film fabrication method of claim 27, wherein the first film formation process is conducted to form a first copper-diffusion barrier film, and the second film formation process is conducted to form a second copper-diffusion barrier film.

35. The film fabrication method of claim 29, further comprising the step of:
etching the dielectric film prior to the first film formation process.

36. The film fabrication method of claim 35, wherein the etching step includes via-hole etching for forming a hole in the dielectric film.

37. The film fabrication method of claim 35, wherein the etching step includes trench etching for forming a groove in the dielectric film.

38. The film fabrication method of claim 27, further comprising the step of:
forming a copper film after the second film formation process.

39. A semiconductor device fabrication method comprising:
a first gas supply step of supplying a first source gas containing a metal-organic compound and without containing a halogen element onto a semiconductor substrate held in a processing chamber and then removing the first source gas from the chamber;
a second gas supply step of supplying a second source gas containing hydrogen or a hydrogen compound onto the semiconductor substrate and then removing the second source gas from the chamber;
a first repetition step of repeating the first and second gas supply steps to form a first film with a predetermined thickness over the semiconductor substrate;
a third gas supply step of supplying a third source gas containing a metal halide compound onto the semiconductor substrate and then removing the third gas from the chamber;
a fourth gas supply step of supplying a plasma-activated fourth source gas containing hydrogen or a hydrogen compound onto the semiconductor substrate and then removing the fourth source gas from the chamber; and
a second repetition step of repeating the third and fourth gas supply steps to form a second film over the first film.

40. A machine readable computer program product installed in a film deposition apparatus to cause the film deposition apparatus to execute:
a first film formation process of repeating
a first step of supplying a first source gas containing a metal-organic compound and without containing a halogen element into the chamber and then removing the first source gas from the chamber; and
a second step of supplying a second source gas containing hydrogen or a hydrogen compound into the chamber and then removing the second source gas from the chamber; and
a second film formation process of repeating
a third step of supplying a third source gas containing a metal halide compound into the chamber and then removing the third gas from the chamber; and
a fourth step of supplying a plasma-activated fourth source gas containing hydrogen or a hydrogen compound into the chamber and then removing the fourth source gas from the chamber.

41. A recording medium storing a program for causing a film deposition apparatus to execute:
a first film formation process of repeating
a first step of supplying a first source gas containing an organic-metal compound and without containing a halogen element into the chamber and then removing the first source gas from the chamber; and
a second step of supplying a second source gas containing hydrogen or a hydrogen compound into the chamber and then removing the second source gas from the chamber; and
a second film formation process of repeating
a third step of supplying a third source gas containing a metal halide compound into the chamber and then removing the third gas from the chamber; and
a fourth step of supplying a plasma-activated fourth source gas containing hydrogen or a hydrogen compound into the chamber and then removing the fourth source gas from the chamber.

42. A film deposition apparatus comprising:
a processing chamber;
a stage configured to hold a substrate to be processed in the processing chamber;
a first gas supply system configured to supply a first source gas or a third source gas into the processing chamber;
a second gas supply system configured to supply a second source gas or a fourth source gas into the processing chamber, independently from the first gas supply system; and
plasma excitation means configured to excite the second source gas or the fourth source gas into plasma.

43. The film deposition apparatus of claim 42, further comprising:
a shower head connected to the first and second gas supply systems and configured to introduce any one of the first through fourth source gases into the processing chamber.

44. The film deposition apparatus of claim 42, wherein the plasma excitation means is a shower head provided in the processing chamber, and high-frequency power is applied to the shower head to perform plasma excitation.

45. The film deposition apparatus of claim 43, wherein the shower head is further configured to perform plasma excitation upon application of high-frequency power.
